(19) United States
(12) Patent Application Publication
(10) Pub. No.: US 2024/0224486 A1
(43) Pub. Date: Jul. 4, 2024

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Ming-Heng TSAI, Taipei City (TW); Chun-Sheng LIANG, Changhua County (TW); Ta-Chun LIN, Hsinchu (TW); Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/149,566

(22) Filed: Jan. 3, 2023

(51) Int. Cl. H10B 10/00; G11C 11/412

(52) U.S. Cl. CPC H10B 10/12; G11C 11/412

(57) ABSTRACT

A device includes a first transistor, a second transistor, and a dielectric wall. The first transistor includes first semiconductor channel layers, a first gate structure, and first source/drain structures on opposite sides of the first gate structure. The second transistor includes second semiconductor channel layers, a second gate structure, and second source/drain structures on opposite sides of the second gate structure. The dielectric wall includes a first sidewall abutting side surfaces of the first semiconductor channel layers in a first cross-sectional view taken along a longitudinal axis of the first gate structure, the first sidewall of the dielectric wall also abutting side surfaces of second semiconductor channel layers in a second cross-sectional view taken along a longitudinal axis of the second gate structure, in which in a top view, the first sidewall of the dielectric wall has a stepped profile.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of a six transistor (6T) SRAM cell.

FIG. 2A illustrates a cell array layout diagram of an SRAM device according to some embodiments of the present disclosure.

FIGS. 2B to 2E are cross-sectional views of an SRAM device according to some embodiments of the present disclosure.

FIGS. 3A to 16E illustrate a method in various stages of forming an SRAM device in accordance with some embodiments of the present disclosure.

FIG. 17 illustrates a cell array layout diagram of an SRAM device according to some embodiments of the present disclosure.

FIG. 18 illustrates a cell array layout diagram of an SRAM device according to some embodiments of the present disclosure.

FIG. 19 illustrates a cell array layout diagram of an SRAM device according to some embodiments of the present disclosure.

FIG. 20 illustrates a cell array layout diagram of an SRAM device according to some embodiments of the present disclosure.

FIG. 21A illustrates a layout diagram of a semiconductor device according to some embodiments of the present disclosure.

FIGS. 21B to 21E are cross-sectional views of an SRAM device according to some embodiments of the present disclosure.

FIG. 22 illustrates a layout diagram of a semiconductor device according to some embodiments of the present disclosure.

FIG. 23 illustrates a layout diagram of a semiconductor device according to some embodiments of the present disclosure.

FIG. 24 illustrates a layout diagram of a semiconductor device according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

The present disclosure will be described with respect to embodiments in a specific context, a static random-access memory (SRAM) formed with a gate-all-around (GAA) configuration. The embodiments of the disclosure may also be applied, however, to a variety of semiconductor devices. Various embodiments will be explained in detail with reference to the accompanying drawings.

Static random-access memory (SRAM) is a type of volatile semiconductor memory that uses bistable latching circuitry to store bits. Bit in an SRAM is stored on four transistors (PU-1, PU-2, PD-1, and PD-2) that form two cross-coupled inverters. This memory cell has two stable states which are used to denote 0 and 1. Two additional access transistors (PG-1 and PG-2) are electrically connected to the two cross-coupled inventers and serve to control the access to a storage cell during read and write operations.

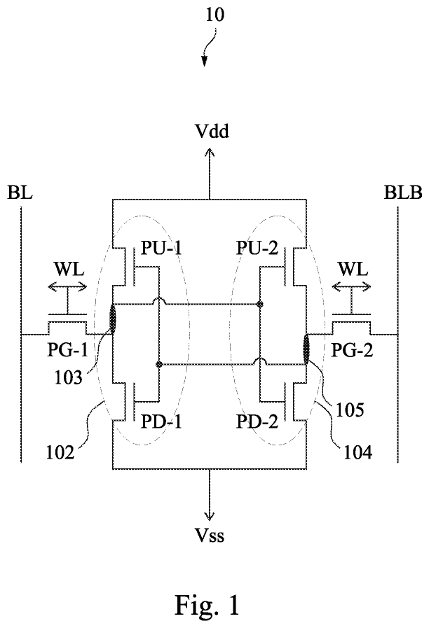

FIG. 1 is a circuit diagram of a six transistor (6T) SRAM cell. The SRAM cell 10 includes a first inverter 102 formed by a pull-up transistor PU-1 and a pull-down transistor PD-1. The SRAM cell 10 further includes a second inverter 104 formed by a pull-up transistor PU-2 and a pull-down transistor PD-2. Furthermore, both the first inverter 102 and second inverter 104 are coupled between a power routing Vdd and a power routing Vss. In some embodiments, the power routing Vss may be ground potential. In some embodiment, the pull-up transistor PU-1 and PU-2 can be p-type transistors while the pull-down transistors PD-1 and PD-2 can be n-type transistors, and the claimed scope of the present disclosure is not limited in this respect.

In FIG. 1, the first inverter 102 and the second inverter 104 are cross-coupled. That is, the first inverter 102 has an input connected to the output of the second inverter 104. Likewise, the second inverter 104 has an input connected to the output of the first inverter 102. The output of the first inverter 102 is referred to as a storage node 103. Likewise, the output of the second inverter 104 is referred to as a storage node 105. In a normal operating mode, the storage node 103 is in the opposite logic state as the storage node 105. By employing the two cross-coupled inverters, the SRAM cell 10 can hold the data using a latched structure so that the stored data will not be lost without applying a refresh cycle as long as power is supplied through Vdd.

In an SRAM device using the 6T SRAM cells, the cells are arranged in rows and columns. The columns of the SRAM array are formed by a bit line pairs, namely a first bit line BL and a second bit line BLB. The cells of the SRAM device are disposed between the respective bit line pairs. As shown in FIG. 1, the SRAM cell 10 is placed between the bit line BL and the bit line BLB.

In FIG. 1, the SRAM cell 10 further includes a first pass-gate transistor PG-1 connected between the bit line BL and the output 103 of the first inverter 102. The SRAM cell 10 further includes a second pass-gate transistor PG-2 connected between the bit line BLB and the output 105 of the second inverter 104. The gates of the first pass-gate transistor PG-1 and the second pass-gate transistor PG-2 are connected to a word line WL, which connects SRAM cells in a row of the SRAM array.

In operation, if the pass-gate transistors PG-1 and PG-2 are inactive, the SRAM cell 10 will maintain the complementary values at storage nodes 103 and 105 indefinitely as long as power is provided through Vdd. This is so because each inverter of the pair of cross coupled inverters drives the input of the other, thereby maintaining the voltages at the storage nodes. This situation will remain stable until the power is removed from the SRAM, or, a write cycle is performed changing the stored data at the storage nodes.

In the circuit diagram of FIG. 1, the pull-up transistors PU-1, PU-2 are p-type transistors. The pull-down transistors PD-1, PD-2, and the pass-gate transistors PG-1, PG-2 are n-type transistors. In some other embodiments, however, the pull-up transistors PU-1, PU-2 are n-type transistors, and the pull-down transistors PD-1, PD-2, and the pass-gate transistors PG-1, PG-2 are p-type transistors.

The structure of the SRAM cell 10 in FIG. 1 is described in the context of the 6T-SRAM. One of ordinary skill in the art, however, should understand that features of the various embodiments described herein may be used for forming other types of devices, such as an 8T-SRAM memory device, or memory devices other than SRAMs, such as standard cell, gated diode or ESD (Electrostatic Discharge) devices. Furthermore, embodiments of the present disclosure may be used as stand-alone memory devices, memory devices integrated with other integrated circuitry, or the like.

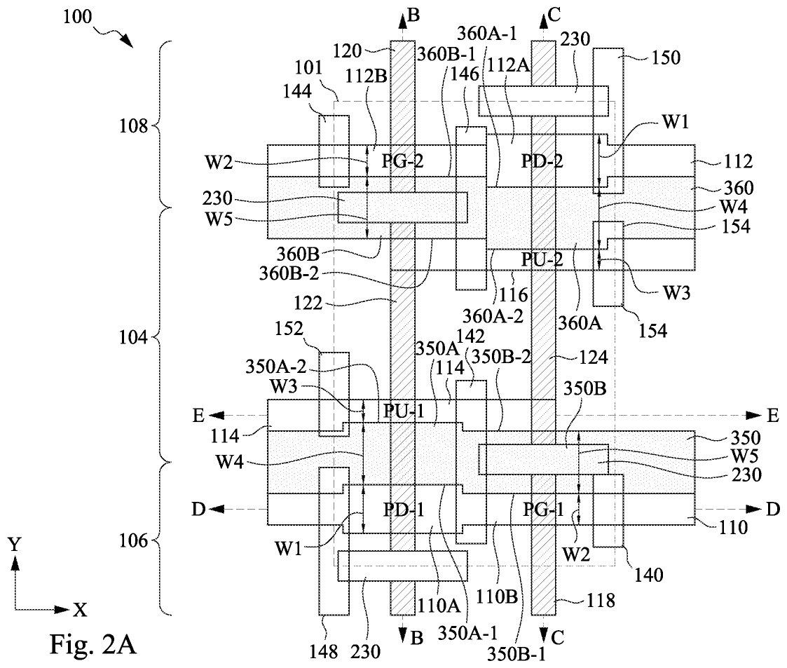

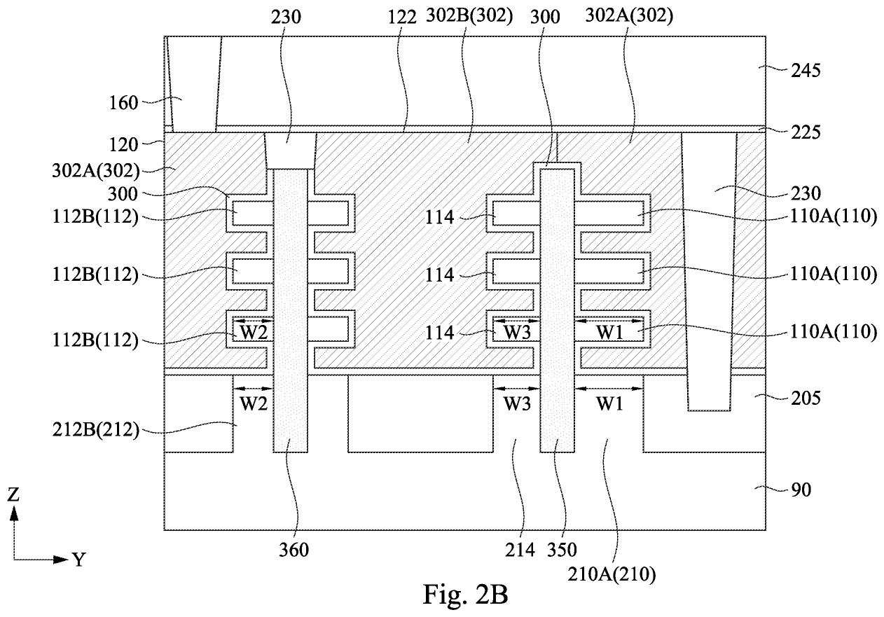

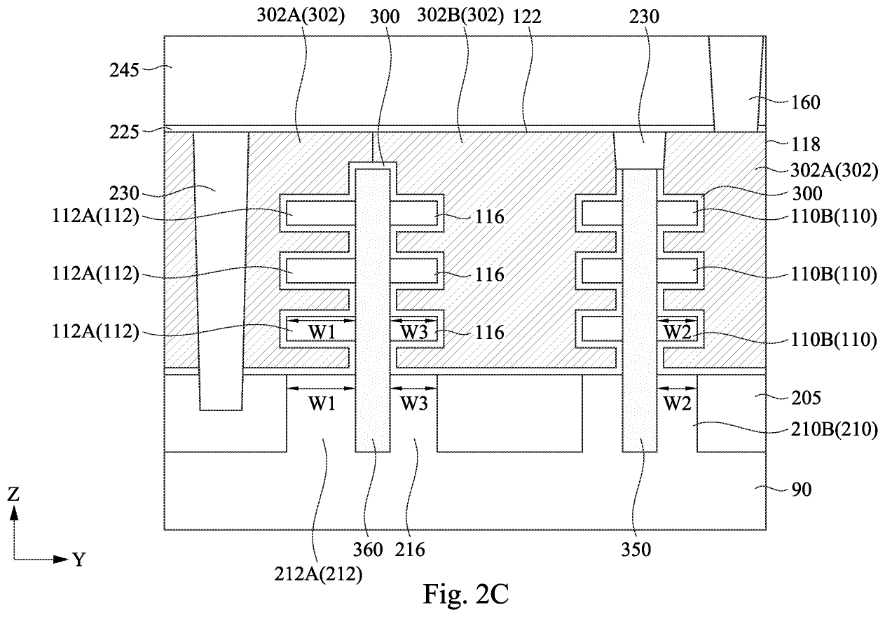

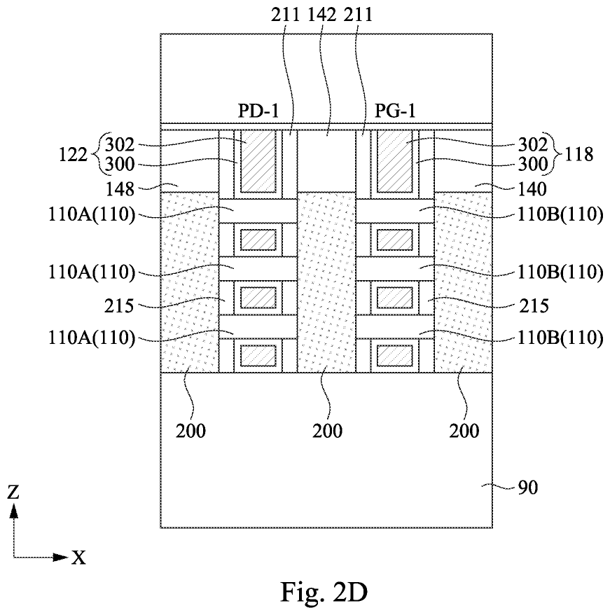

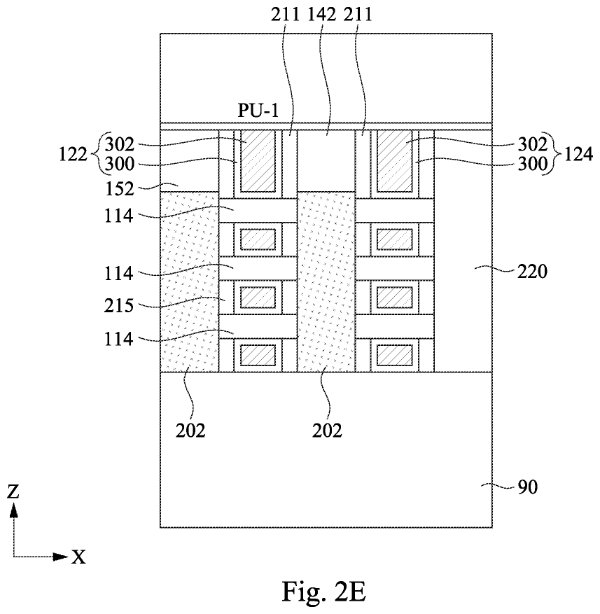

Reference is made to FIGS. 2A to 2E. FIG. 2A illustrates a layout diagram of an SRAM device according to some embodiments of the present disclosure. In some embodiments, FIG. 2A is a top view (plane view) of an SRAM device. FIGS. 2B to 2E are cross-sectional views along lines B-B, C-C, D-D, and E-E of FIG. 2A, respectively. In greater details, FIGS. 2B and 2C are cross-sectional views along the Y-direction, and FIGS. 2D and 2E are cross-sectional views along the X-direction.

Shown there is an SRAM device 100. The SRAM device 100 includes a substrate 90 (see FIGS. 2A to 2E). The substrate 90 may be made of silicon or other semiconductor materials. Alternatively or additionally, the substrate 90 may include other elementary semiconductor materials such as germanium. In some embodiments, the substrate 90 is made of a compound semiconductor such as silicon carbide (SiC), gallium arsenic (GaAs), indium arsenide (InAs), or indium phosphide (InP). In some embodiments, the substrate 90 is made of an alloy semiconductor such as silicon germanium (SiGe), silicon germanium carbide (SiGeC), gallium arsenic phosphide (GaAsP), or gallium indium phosphide (GaInP). In some embodiments, the substrate 90 includes an epitaxial layer. For example, the substrate 90 has an epitaxial layer overlying a bulk semiconductor.

In the top view of FIG. 2A, the SRAM device 100 has an SRAM unit cell 101. In some embodiments, the SRAM device 100 may include a plurality of SRAM unit cells 101 arranged, for example, in a plurality of columns and rows (e.g., to provide a memory array). In some cases, the SRAM unit cell 101 may include an N-well region 104 disposed between two P-well regions 106, 108. In some embodiments, the P-well region 106 includes an N-type pass gate (PG-1) transistor and an N-type pull-down (PD-1) transistor, and the P-well region 108 includes an N-type pass gate (PG-2) transistor and an N-type pull-down (PD-2) transistor. In some examples, the N-well region 104 may include a P-type pull-up (PU-1) transistor and a P-type pull-up (PU-2) transistor. In some embodiments, the SRAM unit cell 101 may include the circuit of the SRAM cell 10 as described in FIG. 1.

In various embodiments, the PG-1, PG-2, PD-1, PD-2, PU-1, and PU-2 transistors are formed with a gate-all-around (GAA) configuration. That is, the channel regions of each of the PG-1, PG-2, PD-1, PD-2, PU-1, and PU-2 transistors may include a plurality of semiconductor channel layers stacked along a vertical direction, and each of the semiconductor channel layers is wrapped around by a respective gate structure. For example, the PG-1 and PD-1 transistors include semiconductor layers 110, the PG-2 and PD-2 transistors include semiconductor layers 112, the PU-1 transistor includes semiconductor layers 114, and the PU-2 transistor includes semiconductor layers 116. In some embodiments, each of the semiconductor layers 110, 112, 114, and 116 has a lengthwise direction extending along the X-direction. In some embodiments, the semiconductor layers 110, 112, 114, and 116 can also be referred to as semiconductor channel layers.

As shown in the cross-sectional views of FIGS. 2B to 2E, the semiconductor layers 110 are stacked along a vertical direction, the semiconductor layers 112 are stacked along a vertical direction, the semiconductor layers 114 are stacked along a vertical direction, and the semiconductor layers 116 are stacked along a vertical direction. In some embodiments, the semiconductor layers 110, 112, 114, and 116 may be made of suitable semiconductor materials, such as silicon, or the like.

The semiconductor layers 110 may include first portions 110A and second portions 110B. In some embodiments, the first portions 110A may serve as channel region of the PD-1 transistor, and the second portions 110B may serve as channel region of the PG-1 transistor. In some embodiments, the first portions 110A and the second portions 110B of the semiconductor layers 110 can be interchangeably referred to as semiconductor layers 110A and 110B, respectively. Similarly, the semiconductor layers 112 may include first portions 112A and second portions 112B. In some embodiments, the first portions 112A may serve as channel region of the PD-2 transistor, and the second portions 112B may serve as channel region of the PG-2 transistor. In some embodiments, the first portions 112A and the second portions 112B of the semiconductor layers 112 can be interchangeably referred to as semiconductor layers 112A and 112B, respectively.

The semiconductor layers 110A have a width W1 along the Y-direction, the semiconductor layers 110B have a width W2 along the Y-direction, and the semiconductor layers 114 have a width W3 along the Y-direction. Similarly, the semiconductor layers 112A have a width W1 along the Y-direction, the semiconductor layers 112B have a width W2 along the Y-direction, and the semiconductor layers 116 have a width W3 along the Y-direction. That is, the semiconductor layers 110A and the semiconductor layers 112A may include substantially a same width along the Y-direction, the semiconductor layers 110B and the semiconductor layers 112B may include substantially a same width along the Y-direction, and the semiconductor layers 114 and the semiconductor layers 116 may include substantially a same width along the Y-direction.

In some embodiments, the width W1 is greater than the width W2, and the width W2 is greater than the width W3. That is, the semiconductor layers 110A are wider than the semiconductor layers 110B along the Y-direction, and the semiconductor layers 110B are wider than the semiconductor layers 114 along the Y-direction. Similarly, the semiconductor layers 112A are wider than the semiconductor layers 112B along the Y-direction, and the semiconductor layers 112B are wider than the semiconductor layers 116 along the Y-direction. In some embodiments, opposite sidewalls of the semiconductor layers 110 each has a stepped sidewall profiles. Similarly, opposite sidewalls of the semiconductor layers 112 each has a stepped sidewall profiles.

As shown in FIGS. 2B to 2E, the SRAM device 100 further includes semiconductor strips 210, 212, 214, and 216 protruding from top surface of the substrate 90. In some embodiments, the semiconductor strip 210 is vertically between the stack of semiconductor layers 110 and the substrate 90, the semiconductor strip 212 is vertically between the stack of semiconductor layers 112 and the substrate 90, the semiconductor strip 214 is vertically between the stack of semiconductor layers 114 and the substrate 90, and the semiconductor strip 216 is vertically between the stack of semiconductor layers 116 and the substrate 90.

The semiconductor strips 210, 212, 214, and 216 may include similar or substantially a same top view profile as the semiconductor layers 110, 112, 114, and 116, respectively. For example, the semiconductor strips 210 may also include a first portion 210A below the first portions 110A of the semiconductor layers 110 and a second portion 210B below the second portions 110B of the semiconductor layers 110. The semiconductor strips 212 may also include a first portion 212A below the first portions 112A of the semiconductor layers 112 and a second portion 212B below the second portions 112B of the semiconductor layers 112. In some embodiments, the first portions 210A and the second portions 210B of the semiconductor strip 210 can be interchangeably referred to as semiconductor strips 210A and 210B, respectively. The first portions 212A and the second portions 212B of the semiconductor strip 212 can be interchangeably referred to as semiconductor strips 212A and 212B, respectively.

In some embodiments, the semiconductor strips 210A and 212A may include a width W1, the semiconductor strips 210B and 212B may include a width W2 and the semiconductor strips 214 and 216 may include a width W3, in which W1>W2>W3. In some embodiments, the semiconductor strips 210 and 212 may include stepped sidewall profiles similar to the semiconductor layers 110 and 112.

The SRAM device 100 further includes dielectric walls 350 and 360. In some embodiments, the dielectric wall 350 is laterally between the semiconductor layers 110 and the semiconductor layers 114, and the dielectric wall 360 is laterally between the semiconductor layers 112 and the semiconductor layers 116. In some embodiments, the dielectric walls 350 and 360 may include dielectric material. Each of the dielectric walls 350 and 360 may be a single-layer or a multi-layer structure. In some embodiments, the dielectric walls 350 and 360 may include be SiO2, SiN, SiCN, SiCON, SiCO, AlO, HfO, other high-k material (k>=7), and composite with multi-layers of above material. In some embodiments, each of the dielectric walls 350 and 360 may include a width in a range from about 5 nm to about 50 nm. If the width is too large (e.g., much larger than 50 nm), the device scale may be unwantedly enlarged. If the width is too low (e.g., much less than 5 nm), the dielectric walls 350 and 360 may be too thin and may not be enough to provide isolation purpose.

With respect to the dielectric wall 350, the dielectric wall 350 may include a first portion 350A and a second portion 350B laterally connected to each other along the X-direction. In some embodiments, the first portion 350A of the dielectric wall 350 is in contact with the semiconductor layers 110A and the semiconductor layers 114, and the second portion of the dielectric wall 350 in contact with the semiconductor layers 110B.

In some embodiments, the first portion 350A and the second portion 350B of the dielectric wall 350 may include a width W4 and a width W5 along the Y-direction, respectively. In the present embodiments, the width W4 and a width W5 are substantially equal to each other. That is, the first portion 350A and the second portion 350B of the dielectric wall 350 may include substantially a same width along the Y-direction.

However, in the top view of FIG. 2A, the outer sidewalls of the first portion 350A are misaligned with the outer sidewalls of the first portion 350B along the X-direction. For example, the first portion 350A of the dielectric wall 350 may include a sidewall 350A-1 in contact with the semiconductor layers 110A, and a sidewall 350A-2 in contact with the semiconductor layers 114. On the other hand, the second portion 350B of the dielectric wall 350 may include a sidewall 350B-1 in contact with the semiconductor layers 110B, and a sidewall 350B-2 opposite to the sidewall 350B-1. In some embodiments, the sidewall 350A-1 of the first portion 350A is misaligned with the sidewall 350B-1 of the second portion 350B along the X-direction. On the other hand, the sidewall 350A-2 of the first portion 350A is misaligned with the sidewall 350B-2 of the second portion 350B along the X-direction. That is, in the top view of FIG. 2A, opposite sidewalls of the dielectric wall 350 each may include a stepped sidewall profile, in which the stepped sidewall profile may include a first segment and a second segment set back from the first segment.

With respect to the dielectric wall 360, the dielectric wall 360 may include a first portion 360A and a second portion 360B laterally connected to each other along the X-direction. In some embodiments, the first portion 360A of the dielectric wall 360 is in contact with the semiconductor layers 112A and the semiconductor layers 116, and the second portion of the dielectric wall 360 in contact with the semiconductor layers 112B.

In some embodiments, the first portion 360A and the second portion 360B of the dielectric wall 360 may include a width W4 and a width W5 along the Y-direction, respectively. In the present embodiments, the width W4 and a width W5 are substantially equal to each other. That is, the first portion 360A and the second portion 360B of the dielectric wall 350 may include substantially a same width along the Y-direction.

However, in the top view of FIG. 2A, the outer sidewalls of the first portion 360A are misaligned with the outer sidewalls of the first portion 360B along the X-direction. For example, the first portion 360A of the dielectric wall 360 may include a sidewall 360A-1 in contact with the semiconductor layers 112A, and a sidewall 360A-2 in contact with the semiconductor layers 116. On the other hand, the second portion 360B of the dielectric wall 360 may include a sidewall 360B-1 in contact with the semiconductor layers 112B, and a sidewall 360B-2 opposite to the sidewall 360B-1. In some embodiments, the sidewall 360A-1 of the first portion 360A is misaligned with the sidewall 360B-1 of the second portion 360B along the X-direction. On the other hand, the sidewall 360A-2 of the first portion 360A is misaligned with the sidewall 360B-2 of the second portion 360B along the X-direction. That is, in the top view of FIG. 2A, opposite sidewalls of the dielectric wall 360 each may include a stepped sidewall profile, in which the stepped sidewall profile may include a first segment and a second segment set back from the first segment.

Each of the PG-1, PG-2, PD-1, PD-2, PU-1, and PU-2 transistors of the SRAM device 100 also include a gate structure. For instance, the PG-1 transistor includes a gate structure 118 that spans perpendicularly across a channel region of the semiconductor layers 110, the PG-2 transistor includes a gate structure 120 that spans perpendicularly across a channel region of the semiconductor layers 112, the PD-1 and PU-1 transistors include a gate structure 122 that spans perpendicularly across a channel region of the semiconductor layers 110 and across a channel region of the semiconductor layers 114, and PD-2 and PU-2 transistors include a gate structure 124 that spans perpendicularly across a channel region of the semiconductor layers 112 and across a channel region of the semiconductor layers 116. In some embodiments, each of the gate structures 118, 120, 122, and 124 has a lengthwise direction extending along the Y-direction.

As shown in the cross-sectional view of FIGS. 2B, 2C, 2D, and 2E, each of the gate structures 118, 120, 122, and 124 include a gate dielectric 300 and a gate electrode 302 over the gate dielectric 300. In some embodiments, the gate dielectric 300 includes one layer of high-k dielectric. In some other embodiments, the gate dielectric 300 includes multi-layer structure, such as an interfacial layer and a high-k dielectric material. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. Examples of interfacial layer include silicon oxide (SiO₂), silicon nitride (SiN), silicon oxynitride (SiON), hBN, aluminum oxide (Al₂O₃), other suitable dielectric material, and/or combinations thereof.

In some embodiments, the gate electrode 302 includes a conductive material and may be selected from a group comprising of polycrystalline-silicon (poly-Si), polycrystalline silicon-germanium (poly-SiGe), metallic nitrides, metallic silicides, metallic oxides, and metals. Examples of metallic nitrides include tungsten nitride, molybdenum nitride, titanium nitride, and tantalum nitride, or their combinations. Examples of metallic silicide include tungsten silicide, titanium silicide, cobalt silicide, nickel silicide, platinum silicide, erbium silicide, or their combinations. Examples of metallic oxides include ruthenium oxide, indium tin oxide, or their combinations. Examples of metals include tantalum, tungsten, titanium, aluminum, copper, molybdenum, nickel, platinum, etc.

In greater details, the gate structure 118 may include a gate electrode 302A and a gate dielectric 300. The gate structure 120 may include a gate electrode 302A and a gate dielectric 300. On the other hand, the gate structure 122 may include a gate electrode 302A over the semiconductor layers 110A and a gate electrode 302B over the semiconductor layers 114. The gate structure 124 may include a gate electrode 302A over the semiconductor layers 112A and a gate electrode 302B over the semiconductor layers 116. In some embodiments, the gate electrodes 302A may include n-type work function metal materials, while the gate electrodes 302B may include p-type work function metal materials. In some embodiments, with respect to the gate structures 122 and 124, the gate electrode 302A is in contact with the gate electrode 302B, and the interface between the gate electrodes 302A and 302B is vertically above the dielectric wall 350 (or dielectric wall 360).

In some embodiments, in the cross-sectional views of FIGS. 2B and 2C, the semiconductor layers 110 each has a sidewall in contact with the dielectric wall 350, and the semiconductor layers 114 each has a sidewall in contact with the dielectric wall 350. Similarly, the semiconductor layers 112 each has a sidewall in contact with the dielectric wall 350, and the semiconductor layers 116 each has a sidewall in contact with the dielectric wall 350.

In various embodiments, each of the PG-1, PG-2, PD-1, PD-2, PU-1, and PU-2 transistors of the SRAM device 100 includes source/drain regions on portions of their respective semiconductor layers adjacent to and on either side of their respective gate structures, and thus adjacent to and on either side of their respective channel regions.

As shown in the cross-sectional view of FIGS. 2D and 2E, the SRAM device 100 includes a plurality of source/drain epitaxy structures 200 and 202. The source/drain epitaxy structures 200 may be formed on opposites sides of the semiconductor layers 110B and on opposite sides of the gate structure 118. As a result, the semiconductor layers 110B, the gate structure 118, and the source/drain epitaxy structures 200 may collectively serve as the PG-1 transistor. The source/drain epitaxy structures 200 may be formed on opposites sides of the semiconductor layers 110A and on opposite sides of the gate structure 122. As a result, the semiconductor layers 110A, the gate structure 122, and the source/drain epitaxy structures 200 may collectively serve as the PD-1 transistor. The source/drain epitaxy structures 202 may be formed on opposites sides of the semiconductor layers 114 and on opposite sides of the gate structure 122. As a result, the semiconductor layers 114, the gate structure 122 and the source/drain epitaxy structures 202 may collectively serve as the PU-1 transistor. The source/drain epitaxy structures 202 may be formed on opposites sides of the semiconductor layers 116 and on opposite sides of the gate structure 124. As a result, the semiconductor layers 116, the gate structure 124, and the source/drain epitaxy structures 202 may collectively serve as the PU-2 transistor. The source/drain epitaxy structures 200 may be formed on opposites sides of the semiconductor layers 112A and on opposite sides of the gate structure 124. As a result, the semiconductor layers 112A, the gate structure 124, and the source/drain epitaxy structures 200 may collectively serve as the PD-2 transistor. The source/drain epitaxy structures 200 may be formed on opposites sides of the semiconductor layers 112B and on opposite sides of the gate structure 120. As a result, the semiconductor layers 112B, the gate structure 120, and the source/drain epitaxy structures 200 may collectively serve as the PG-2 transistor.

In some embodiments, the source/drain epitaxy structures 200 and 202 may include different conductivity types. In some embodiments where the PD-1, PD-2, PG-1, and PG-2 transistors are n-type transistors and the PU-1 and PU-2 transistors are p-type transistors, the source/drain epitaxy structures 200 are n-type epitaxy structures, and the source/drain epitaxy structures 202 are p-type epitaxy structures. On the other hand, in some embodiments where the PD-1, PD-2, PG-1, and PG-2 transistors are p-type transistors and the PU-1 and PU-2 transistors are n-type transistors, the source/drain epitaxy structures 200 are p-type epitaxy structures, and the source/drain epitaxy structures 202 are n-type epitaxy structures. Examples of n-type dopants can be phosphorus (P), arsenic (As), or antimony (Sb), or the like. Examples of p-type dopants can be boron (B), gallium (Ga), indium (In), aluminium (Al), or the like. In some embodiments, the source/drain epitaxy structures 200 and 202 may include Si, SiGe, Ge, III-V materials, or the like. In some embodiments, the source/drain epitaxy structures 200 and 202 may include epitaxial material for N-type device (e.g., NFET), such as SiP, SiAs, SiC, or the like. On the other hand, the source/drain epitaxy structures 200 and 202 may include epitaxial material for P-type device (e.g., PFET), such as SiGeB, SiCB, or the like.

As shown in the cross-sectional view of FIGS. 2B and 2C. The SRAM device 100 may include isolation structures 205 laterally surrounding semiconductor strips 210, 212, 214, and 216. The isolation structures 205 may be shallow trench isolation (STI) structures, suitable isolation structures, combinations of the foregoing, or the like. In some embodiments, the isolation structures 205 may be made of oxide (e.g., silicon oxide) or nitride (e.g., silicon nitride). In some other embodiments, each of the isolation structures 205 may include a dielectric layer and a dielectric liner lining the dielectric layer, in which the dielectric liner and the dielectric layer are made of different materials, for example, the dielectric liner may be silicon nitride, and the dielectric layer may be silicon oxide.

The SRAM device 100 further includes gate spacers 211 disposed on opposite sidewalls of each of the gate structures 118, 120, 122, and 124. In some embodiments, the gate spacers 211 may be formed by insulating dielectric material, such as a silicon nitride-based material. Examples of the silicon nitride-based material can be SiN, SiON, SiOCN or SiCN and combinations thereof.

The SRAM device 100 further includes inner spacers 215 vertically between two adjacent semiconductor layers 110, 112, 114, and 116. The inner spacers 215 may also be in contact with the source/drain epitaxy structures 200 and 202. In some embodiments, the inner spacers 215 may be formed by insulating dielectric material, such as a silicon nitride-based material. Examples of the silicon nitride-based material can be SiN, SiON, SiOCN or SiCN and combinations thereof.

The SRAM device 100 further includes an interlayer dielectric (ILD) layer 220 (see FIG. 2E). In some embodiments, the ILD layer 220 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

The SRAM device 100 further includes gate-cut dielectric structures 230 disposed on lateral ends of each of the gate structures 118, 120, 122, and 124. For example, in FIG. 2B, one of the gate-cut structures 230 is disposed on a top surface of the dielectric wall 360 and laterally separates the gate structures 120 and 122. Another one of the gate-cut structures 230 extends into the isolation structure 205 and in contact with a sidewall of the gate structure 122. In FIG. 2C, one of the gate-cut structures 230 is disposed on a top surface of the dielectric wall 350 and laterally separates the gate structures 118 and 124. Another one of the gate-cut structures 230 extends into the isolation structure 205 and in contact with a sidewall of the gate structure 124. In some embodiments, the gate-cut dielectric structures 230 may be in contact with the gate dielectric 300 and the gate electrode 302. In some embodiments, the gate-cut dielectric structures 230 may include SiO₂, SiN, SiON, SiOCN or SiCN and combinations thereof.

A plurality of contacts may be directly (physically) connected to the source/drain regions of the SRAM device 100. For example, the PG-1 transistor may include a source/drain contact 140 (first bit line node ‘BL’) and a source/drain contact 142 (first common drain) connected to respective source/drain epitaxy structures 200 of the PG-1 transistor. For example, the source/drain contact 140 may be a source contact, while the source/drain contact 142 may be a drain contact. In some embodiments, the source/drain contact 140 and the source/drain contact 142 are in contact with top surfaces of the respective source/drain epitaxy structures 200 of the PG-1 transistor.

The PG-2 transistor may include a source/drain contact 144 (second bit line node ‘BLB’) and a source/drain contact 146 (second common drain) connected to respective source/drain regions of the PG-2 transistor. For example, the source/drain contact 144 may be a source contact, while the source/drain contact 146 may be a drain contact. In some embodiments, the source/drain contact 144 and the source/drain contact 146 are in contact with top surfaces of the respective source/drain epitaxy structures 200 of the PG-2 transistor.

The PD-1 transistor may include a source/drain contact 148 (V_{SS} node) and the source/drain contact 142 (first common drain) connected to respective source/drain epitaxy structures 200 of the PD-1 transistor. For example, the source/drain contact 148 may be a source contact, while the source/drain contact 142 may be a drain contact.

The PD-2 transistor may include a source/drain contact 150 (V_{SS} node) and the source/drain contact 146 (second common drain) connected to respective source/drain epitaxy structures 200 of the PD-2 transistor. For example, the source/drain contact 150 may be a source contact, while the source/drain contact 146 may be a drain contact.

The PU-1 transistor may include a source/drain contact 152 (V_{dd} node), and the source/drain contact 142 (first common drain) connected to respective source/drain epitaxy structures 202 of the PU-1 transistor. For example, the source/drain contact 152 may be a source contact, while the source/drain contact 142 may be a drain contact. In some embodiments, the source/drain contact 152 is in contact with the top surface of the corresponding source/drain epitaxy structure 202. Moreover, the source/drain contact 142 is in contact with a top surface of the respective source/drain epitaxy structure 202 of the PU-1 transistor.

The PU-2 transistor may include a source/drain contact 154 (V_{dd} node) and the source/drain contact 146 (second common drain) connected to respective source/drain epitaxy structures 202 of the PU-2 transistor. For example, the source/drain contact 154 may be a source contact, while the source/drain contact 146 may be a drain contact. In some embodiments, the source/drain contact 154 is in contact with the top surface of the corresponding source/drain epitaxy structure 202. Moreover, the source/drain contact 146 is in contact with a top surface of the respective source/drain epitaxy structures 202 of the PU-2 transistor.

In FIGS. 2D and 2E, the source/drain contact 142 may be in contact with the source/drain epitaxy structure 200 of the PG-1 and PD-1 transistors and the source/drain epitaxy structure 202 of the PU-1 transistor. Accordingly, the PG-1, PD-1, and PU-1 transistors are electrically coupled to each other (see FIG. 2A). Similarly, the source/drain contact 146 may be in contact with the source/drain epitaxy structure 200 of the PG-2 and PD-2 transistors and the source/drain epitaxy structure 202 of the PU-2 transistor. Accordingly, the PG-2, PD-2, and PU-2 transistors are electrically coupled to each other (see FIG. 2A).

The SRAM device 100 further includes an etch stop layer (ESL) 225 covering the top surface of each of the gate structures 118, 120, 122, and 124, and may over top surfaces of the gate spacers 211. In some embodiments, the gate-top dielectric layers 225 may include SiO₂, SiN, SiON, SiOCN or SiCN and combinations thereof.

The SRAM device 100 further includes further includes an interlayer dielectric (ILD) layer 245 disposed over the etch stop layer 225. In some embodiments, the ILD layer 245 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

The SRAM device 100 further includes vias 160 disposed in the ILD layer 245 and the ESL 225. For example, in FIGS. 2B and 2C, vias 160 are in contact with gate structures 118 and 120. In some embodiments, the vias 160 are made of conductive material, such as metal. In some embodiments, the conductive material may include W, Ru, Co, Cu, Ti, TiN, Ta, TaN, Mo, Ni, or the like.

With respect to FIGS. 1 and 2A to 2E, the SRAM device 100 is similar to the SRAM cell of FIG. 1, which may include a bit line BL, a bit line BLB, a word line WL, a power routing Vss, and a power routing Vdd. For example, the bit line BL may be electrically connected to the corresponding source/drain epitaxy structures 200 of the PG-1 transistor, and the bit line BLB may be electrically connected to the corresponding source/drain epitaxy structures 200 of the PG-1 transistor. The word line WL may be electrically connected to the gate structure 118 of the PG-1 transistor and the gate structure 120 of the PG-1 transistor. The power routing Vdd may be electrically connected to the source/drain epitaxy structures 202 of the PU-1 and PU-2 transistors. The power routing Vss may be electrically connected to the source/drain epitaxy structures 200 of the PD-1 and PD-2 transistors.

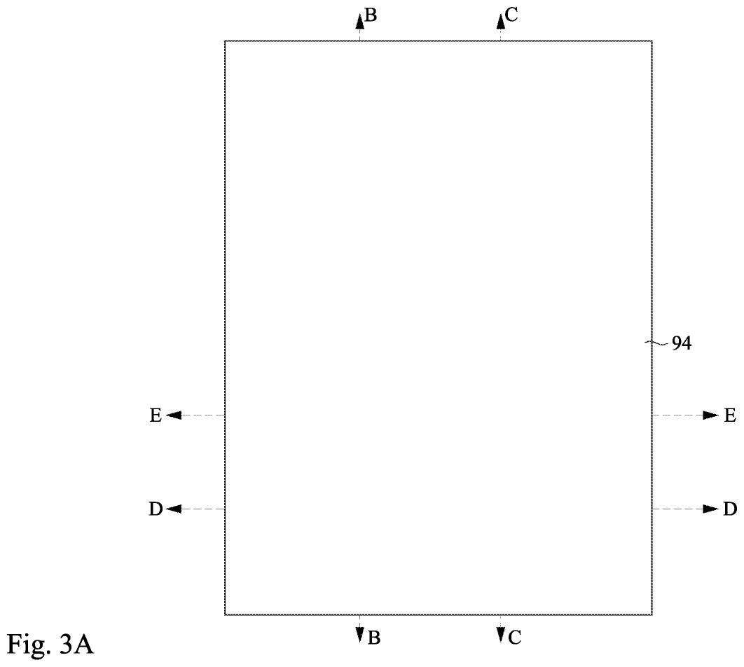

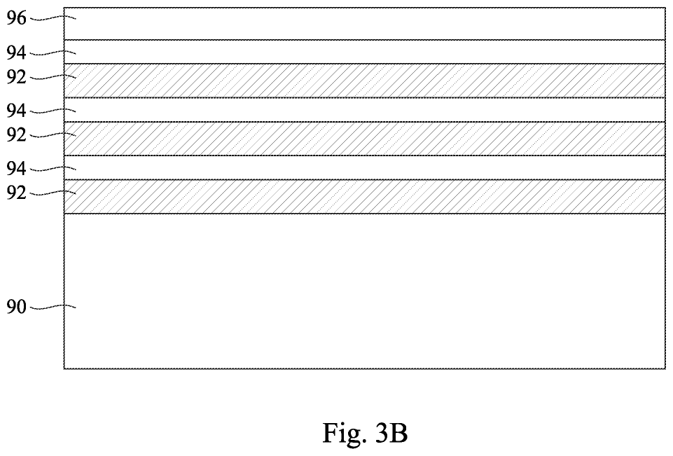

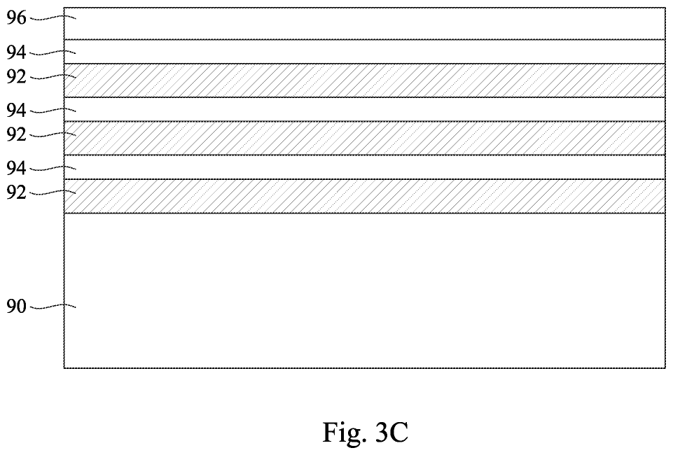

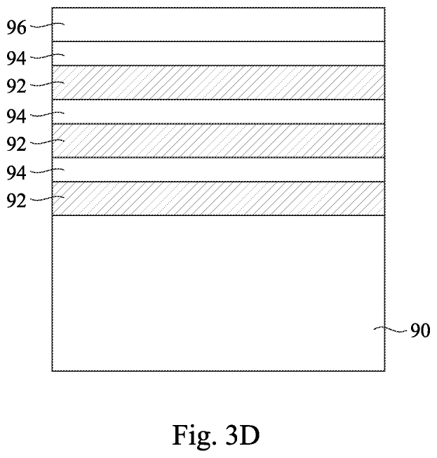

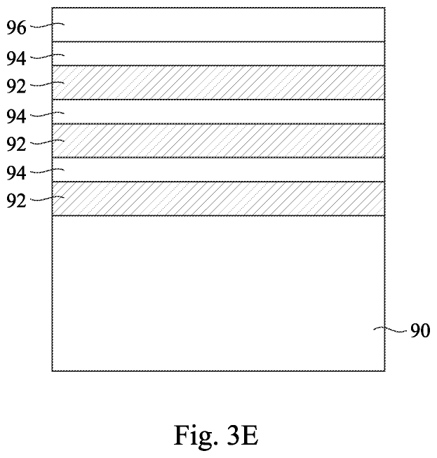

FIGS. 3A to 16E illustrate a method in various stages of forming an SRAM device in accordance with some embodiments of the present disclosure. It is noted that some elements described in FIGS. 3A to 16E are similar to or the same as those described in FIGS. 2A to 2E, such elements are labeled the same, and relevant details will not be repeated for brevity.

Reference is made to FIGS. 3A to 3E, in which FIG. 3A is a cell array layout diagram of an SRAM device, FIGS. 3B, 3C, 3D, and 3E are cross-sectional views along lines B-B, C-C, D-D, E-E of FIG. 3A, respectively. First semiconductor materials 92 and second semiconductor materials 94 are alternately deposited over a substrate 90. Afterward, a hard mask layer 96 is deposited over the topmost one of the second semiconductor materials 94.

The first semiconductor materials and the second semiconductor materials may include different materials and/or components, such that the first semiconductor materials and the second semiconductor materials have different etching rates. In some embodiments, the first semiconductor material is made from SiGe. The germanium percentage (atomic percentage concentration) of the first semiconductor material is in the range between about 10 percent and about 20 percent, while higher or lower germanium percentages may be used. It is appreciated, however, that the values recited throughout the description are examples, and may be changed to different values. For example, the first semiconductor material may be Si_{0.8}Ge_{0.2} or Si_{0.9}Ge_{0.1}, in which the proportion between Si and Ge may vary from embodiments, and the disclosure is not limited thereto. The second semiconductor material may be pure silicon layers that are free of germanium. The second semiconductor material may also be substantially pure silicon layers, for example, with a germanium percentage lower than about 1 percent. In some embodiments, the first semiconductor material has a higher germanium atomic percentage concentration than the second semiconductor material. The first semiconductor material and the second semiconductor material may be formed by chemical vapor deposition (CVD), molecular beam epitaxy (MBE), or other suitable process(es). In some embodiments, the first semiconductor material and the second semiconductor material are formed by an epitaxy growth process, and thus the first semiconductor material and the second semiconductor material can also be referred to as epitaxial layers in this content.

The hard mask layer 96 may include dielectric materials. In some embodiment, the hard mask layer 96 may include a pad layer and a mask layer over the pad layer. The pad layer may be a thin film comprising silicon oxide formed, for example, using a thermal oxidation process. The pad layer may act as an adhesion layer between the topmost one of the second semiconductor materials 94 and the mask layer. In some embodiments, the mask layer is formed of silicon nitride, for example, using low-pressure chemical vapor deposition (LPCVD). In other embodiments, the mask layer is formed by thermal nitridation of silicon, plasma enhanced chemical vapor deposition (PECVD), or plasma anodic nitridation. The hard mask layer 96 is used as a hard mask during subsequent photolithography processes.

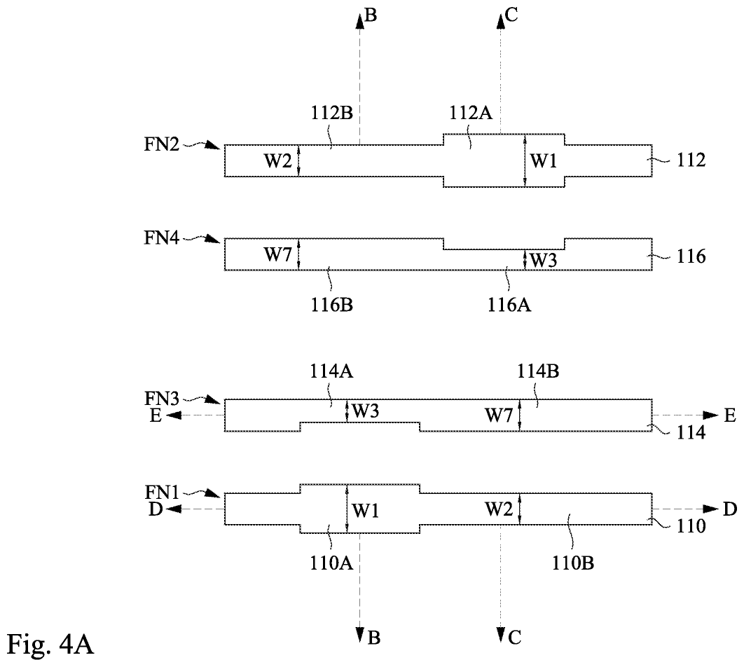

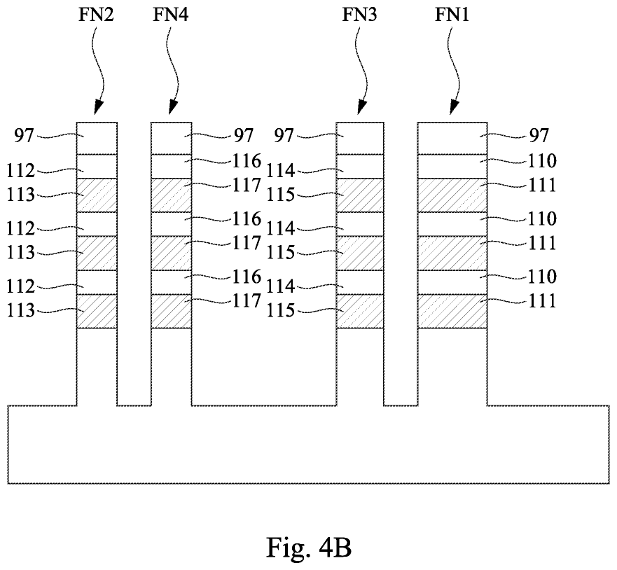

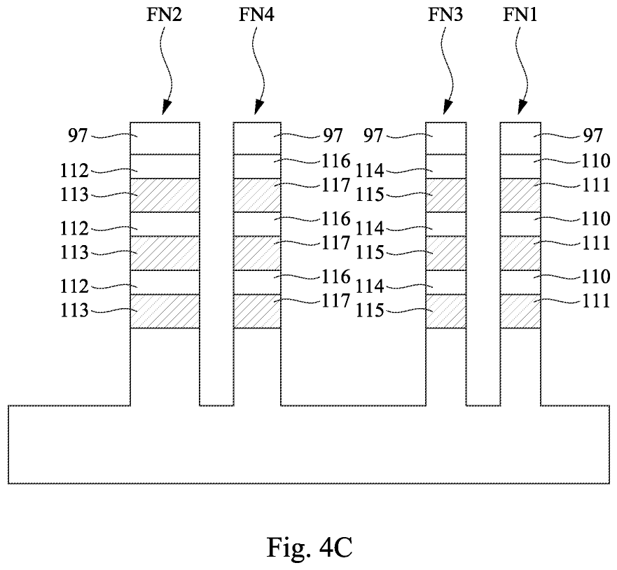

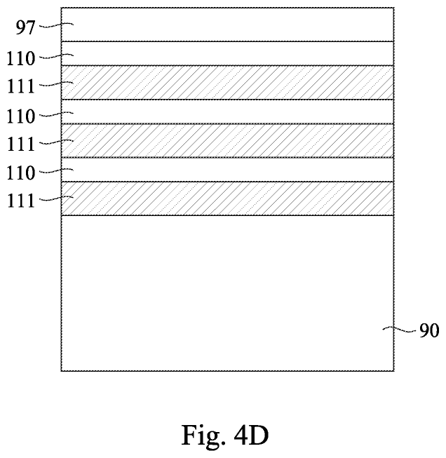

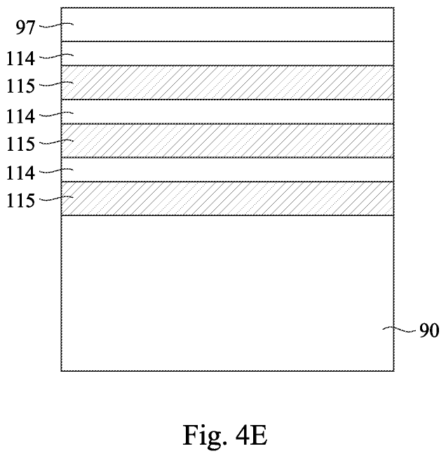

Reference is made to FIGS. 4A to 4E, in which FIG. 4A is a cell array layout diagram of an SRAM device, FIGS. 4B, 4C, 4D, and 4E are cross-sectional views along lines B-B, C-C, D-D, E-E of FIG. 4A, respectively. The hard mask layer 96, the first semiconductor materials 92, the second semiconductor materials 94, and the substrate 90 are patterned to form fin structures FN1, FN2, FN3, and FN4. In some embodiments, the fin structures FN1, FN2, FN3, and FN4 may be formed by, for example, forming a patterned photoresist over the hard mask layer 96, in which the patterned photoresist defines the top profiles of the fin structures FN1, FN2, FN3, and FN4. An etching process may be performed to remove portions of the hard mask layer 96, the first semiconductor materials 92, the second semiconductor materials 94, and the substrate 90 that are exposed by the patterned photoresist. In some embodiments, the fin structures FN1, FN2, FN3, and FN4 can also be referred to as epitaxial stacks.

In some embodiment, the fin structure FN1 includes a semiconductor strip 210, semiconductor layers 110 and 111 alternately stacked over the semiconductor strip 210, and a hard mask 97 over the topmost one of the semiconductor layers 110. The fin structure FN2 includes a semiconductor strip 212, semiconductor layers 112 and 113 alternately stacked over the semiconductor strip 212, and a hard mask 97 over the topmost one of the semiconductor layers 112. The fin structure FN3 includes a semiconductor strip 214, semiconductor layers 114 and 115 alternately stacked over the semiconductor strip 214, and a hard mask 97 over the topmost one of the semiconductor layers 114. The fin structure FN4 includes a semiconductor strip 216, semiconductor layers 116 and 117 alternately stacked over the semiconductor strip 216, and a hard mask 97 over the topmost one of the semiconductor layers 116. In some embodiments, the semiconductor layers 111, 113, 115, and 117 are remaining portions of the first semiconductor materials 92, the semiconductor layers 110, 112, 114, and 116 are remaining portions of the second semiconductor materials 94, and the hard masks 97 are remaining portions of the hard mask layer 96. In some embodiments, the semiconductor layers 111, 113, 115, and 117 can also be referred to as sacrificial layers.

FIG. 4A shows a top view profile of the fin structures FN1, FN2, FN3, and FN4. Here, the semiconductor layers 110, 112, 114, and 116 are taken as examples. Each of the semiconductor layers 110 may include a first portion 110A and a second portion 110B connected to the first portion 110A, in which the first portion 110A and the second portion 110B have a width W1 and a width W2 along the Y-direction, respectively. Each of the semiconductor layers 112 may include a first portion 112A and a second portion 112B connected to the first portion 112A, in which the first portion 112A and the second portion 112B have a width W1 and a width W2 along the Y-direction, respectively. Each of the semiconductor layers 114 may include a first portion 114A and a second portion 114B connected to the first portion 114A, in which the first portion 114A and the second portion 114B have a width W3 and a width W7 along the Y-direction, respectively. Each of the semiconductor layers 116 may include a first portion 116A and a second portion 116B connected to the first portion 116A, in which the first portion 116A and the second portion 116B have a width W3 and a width W7 along the Y-direction, respectively. In some embodiments, the width W1 is greater than the width W2, and the width W7 is greater than the width W3. The width W2 is greater than the width W3. In some embodiments, the width W7 may be substantially equal to the width W2.

In some embodiments, each of the semiconductor layers 110 may include stepped sidewall profiles. For example, opposite sidewalls of each semiconductor layer 110 both include a stepped sidewall profile. That is, opposite sidewalls of the first portions 110A of the semiconductor layer 110 are misaligned with opposite sidewalls of the second portions 110B of the semiconductor layer 110. Similarly, each of the semiconductor layers 110 may include stepped sidewall profiles. For example, opposite sidewalls of each semiconductor layer 112 both include a stepped sidewall profile. That is, opposite sidewalls of the first portions 112A of the semiconductor layer 112 are misaligned with opposite sidewalls of the second portions 112B of the semiconductor layer 112.

However, each of the semiconductor layers 114 may include a stepped sidewall profile and a linear sidewall profile. For example, a sidewall of each semiconductor layer 114 includes a stepped sidewall profile, while another sidewall of each semiconductor layer 114 includes a linear sidewall profile. That is, a sidewall of the first portions 114A of the semiconductor layer 114 is misaligned with a sidewall of the second portions 114B of the semiconductor layer 114, while another sidewall of the first portions 114A of the semiconductor layer 114 is aligned with another sidewall of the second portions 114B of the semiconductor layer 114. Similarly, each of the semiconductor layers 116 may include a stepped sidewall profile and a linear sidewall profile. For example, a sidewall of each semiconductor layer 116 includes a stepped sidewall profile, while another sidewall of each semiconductor layer 116 includes a linear sidewall profile. That is, a sidewall of the first portions 116A of the semiconductor layer 116 is misaligned with a sidewall of the second portions 116B of the semiconductor layer 116, while another sidewall of the first portions 116A of the semiconductor layer 116 is aligned with another sidewall of the second portions 116B of the semiconductor layer 116.

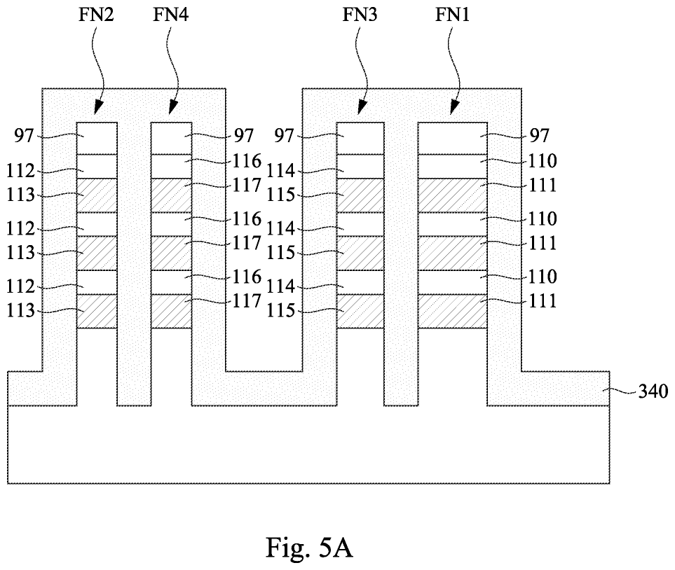

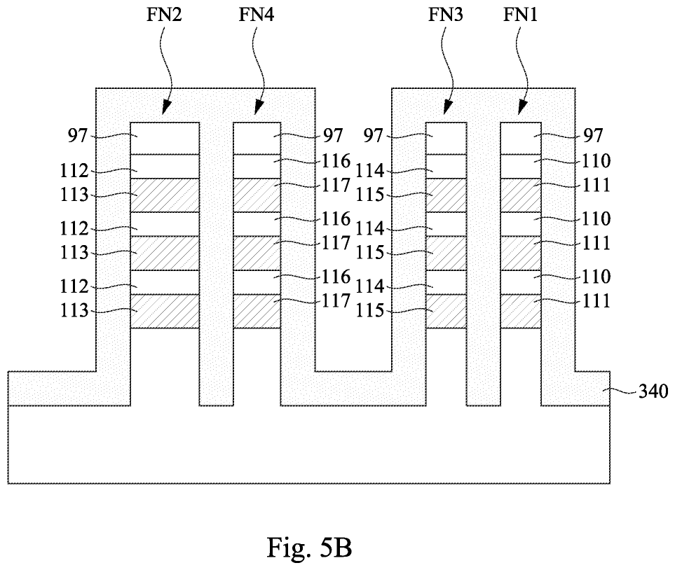

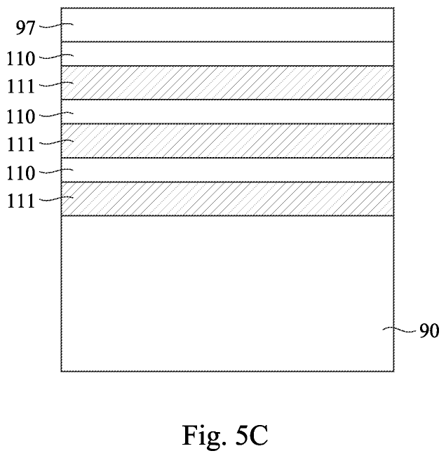

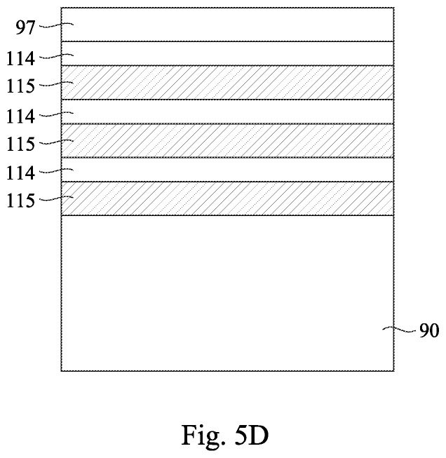

Reference is made to FIGS. 5A to 5D, in which FIGS. 5A to 5D follow the cross-sectional views of FIGS. 4B to 4E, respectively. A dielectric film 340 is formed covering the fin structures FN1, FN2, FN3, and FN4. For example, the dielectric film 340 is conformally deposited on the structure shown in in FIGS. 4B to 4E using CVD, ALD, or a suitable method. In some embodiments, the dielectric film 340 may completely fill the trench between the fin structures FN1 and FN3, and the trench between the fin structures FN2 and FN4, which are narrower than the trench between the fin structure FN3 and FN4. However, the dielectric film 340 may not completely fill the trench between fin structure FN3 and FN4.

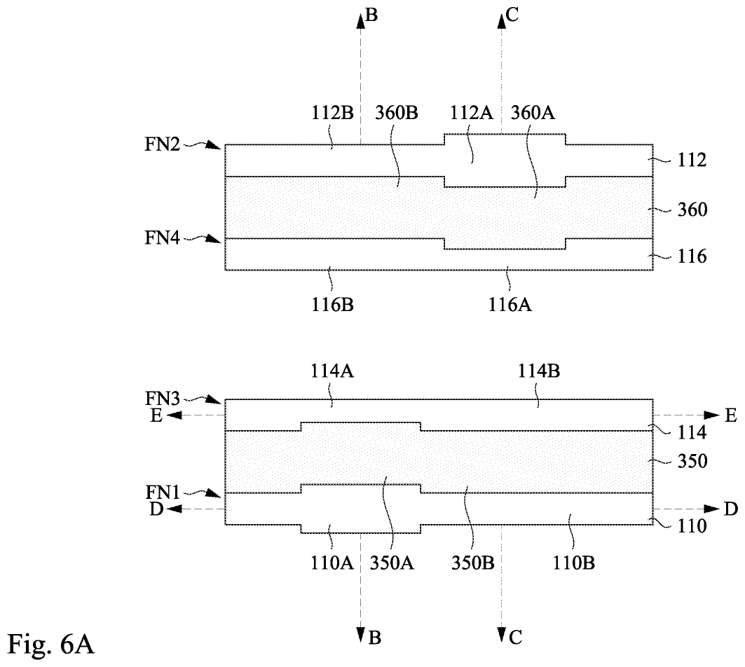

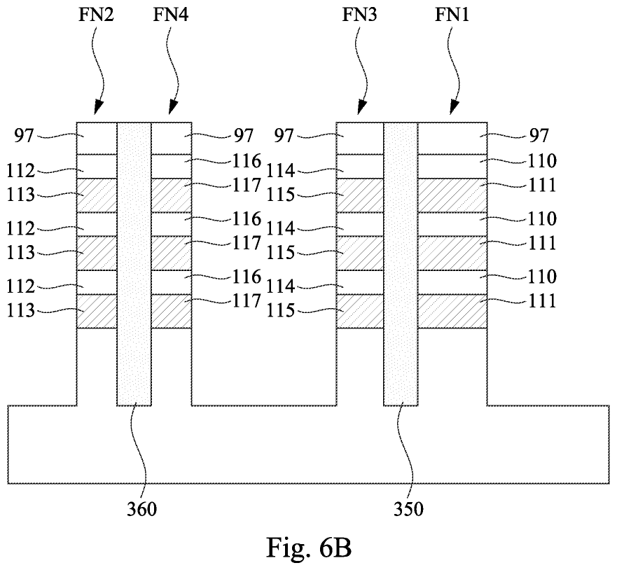

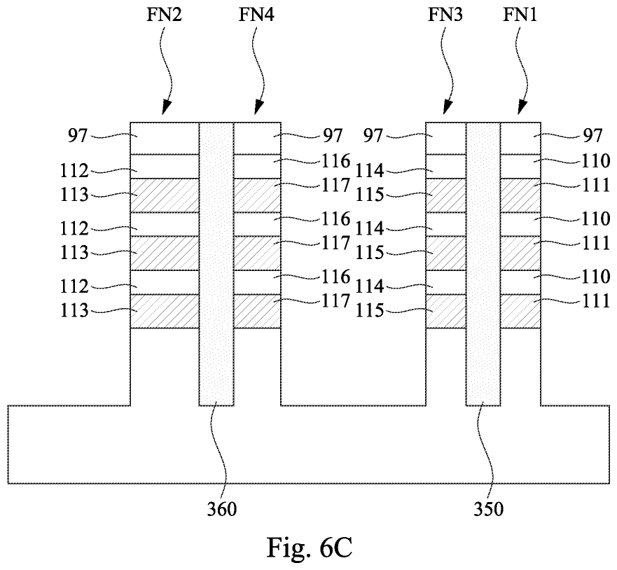

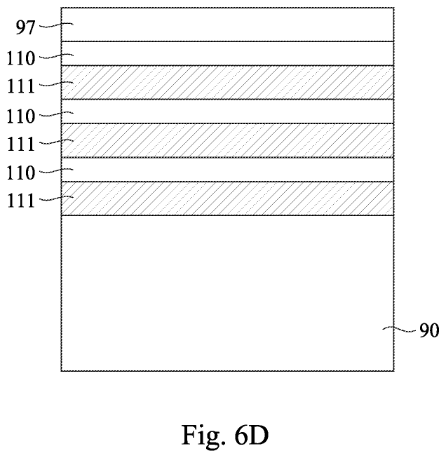

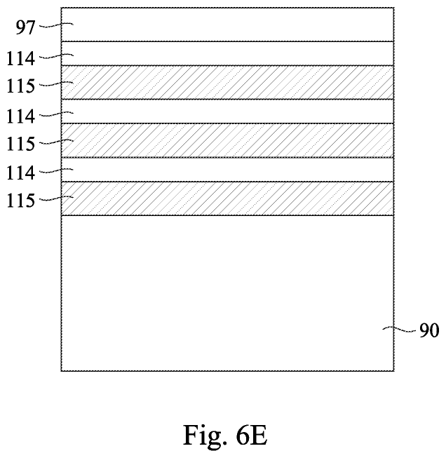

Reference is made to FIGS. 6A to 6E, in which FIG. 6A is a cell array layout diagram of an SRAM device, FIGS. 6B, 6C, 6D, and 6E are cross-sectional views along lines B-B, C-C, D-D, E-E of FIG. 6A, respectively. An etching process is performed to etch back the dielectric film 340, such that portions of the dielectric film 340 remain between the fin structures FN1 and FN3 and also remain between the fin structures FN2 and FN4. However, the wider trench between fin structure FN3 and FN4 may allow etchant to etch sidewalls and bottom surface of the dielectric film 340 inside the trench between fin structure FN3 and FN4, such that the dielectric film 340 are removed from the wider trench in a faster rate than from the narrower trenches between the fin structures FN1 and FN3 and between the fin structures FN2 and FN4. As a result, the remaining portion of the dielectric film 340 between the fin structures FN1 and FN3 can be referred to as dielectric wall 350, and the remaining portion of the dielectric film 340 between the fin structures FN1 and FN3 can be referred to as dielectric wall 360.

In some embodiments, the dielectric film 340 may be etched back in a dry etching process that uses oxygen, nitrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof.

In the top view of FIG. 6A, the dielectric wall 350 may include a first portion 350A and a second portion 350B connected to the first portion 350A, and the dielectric wall 360 may include a first portion 360A and a second portion 360B connected to the first portion 360A. The top view profiles of the dielectric walls 350 and 360 have been described in FIG. 2A, and thus relevant details will not be repeated for brevity.

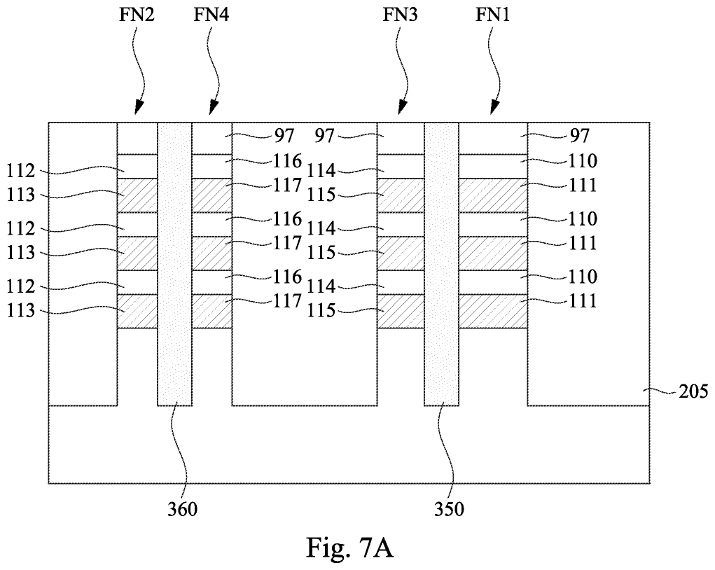

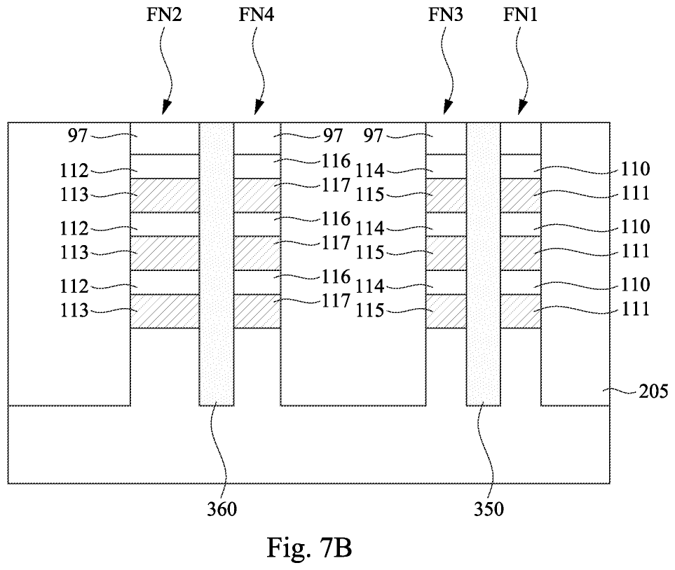

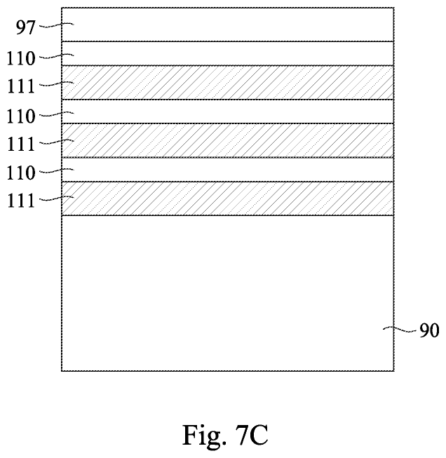

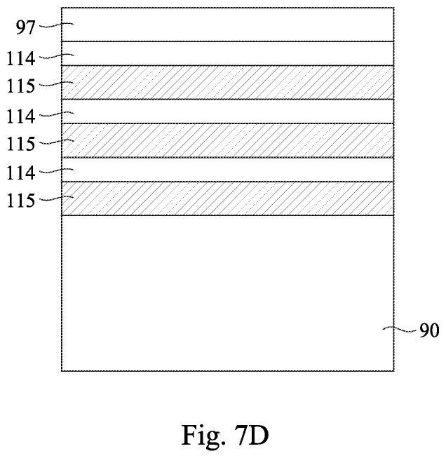

Reference is made to FIGS. 7A to 7D, in which FIGS. 7A to 7D follow the cross-sectional views of FIGS. 6B to 6E, respectively. Isolation structures 205 are formed over the substrate 90 and laterally surrounding the fin structures FN1, FN2, FN3, and FN4. The isolation structures 205 may be formed by, for example, depositing a dielectric material blanket over the substrate 90, and then performing a planarization process, such as CMP, to remove excess dielectric material until the hard masks 97 of the fin structures FN1, FN2, FN3, and FN4 are exposed. The isolation structures 205 may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the isolation structures 205 are silicon oxide formed by a FCVD process.

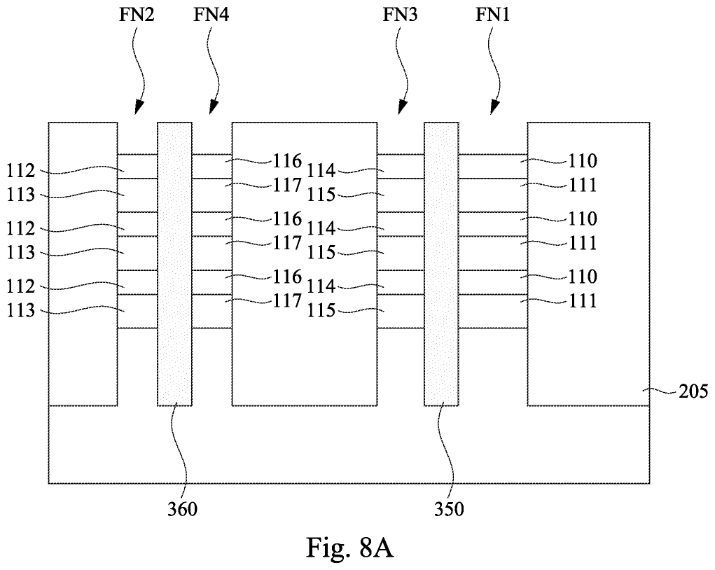

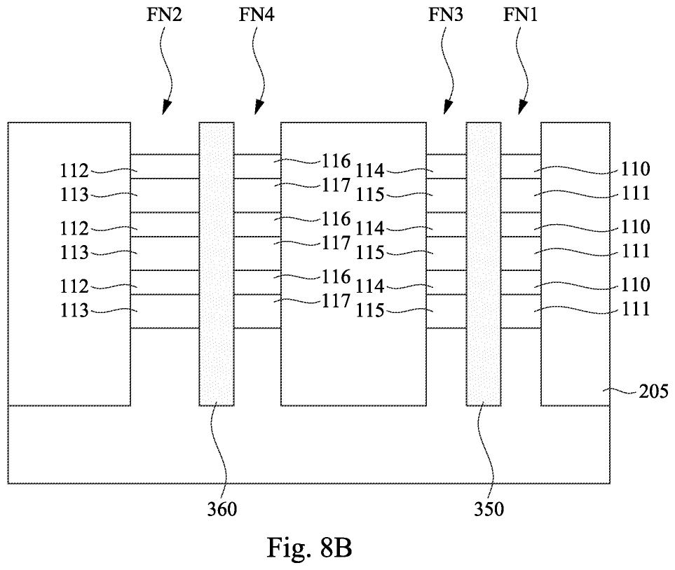

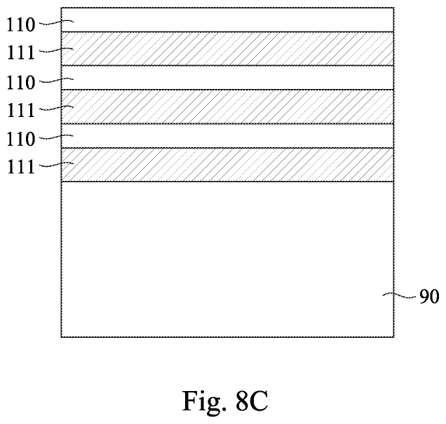

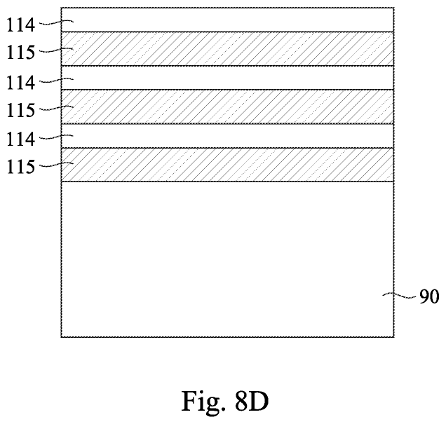

Reference is made to FIGS. 8A to 8D, in which FIGS. 8A to 8D follow the cross-sectional views of FIGS. 7A to 7D, respectively. A first etching process is performed to remove the hard masks 97 of the fin structures FN1, FN2, FN3, and FN4, such that top surfaces of the semiconductor layers 110, 112, 114, and 116 are exposed. In some embodiments, the first etching process may include dry etch, wet etch, or combinations thereof.

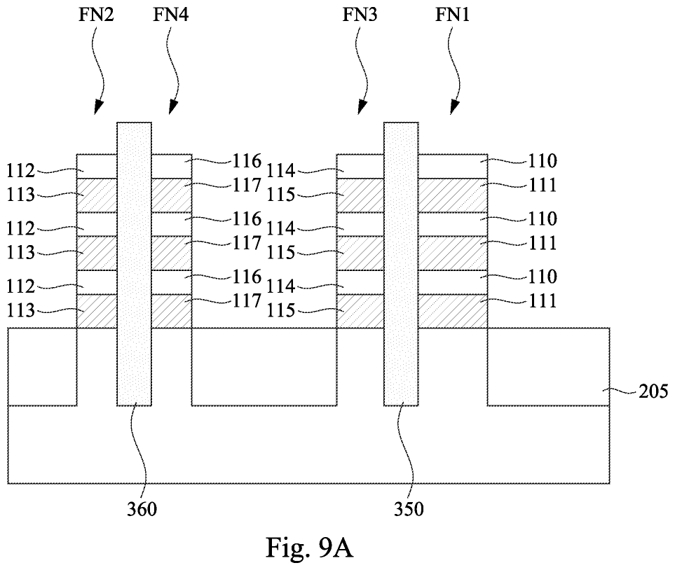

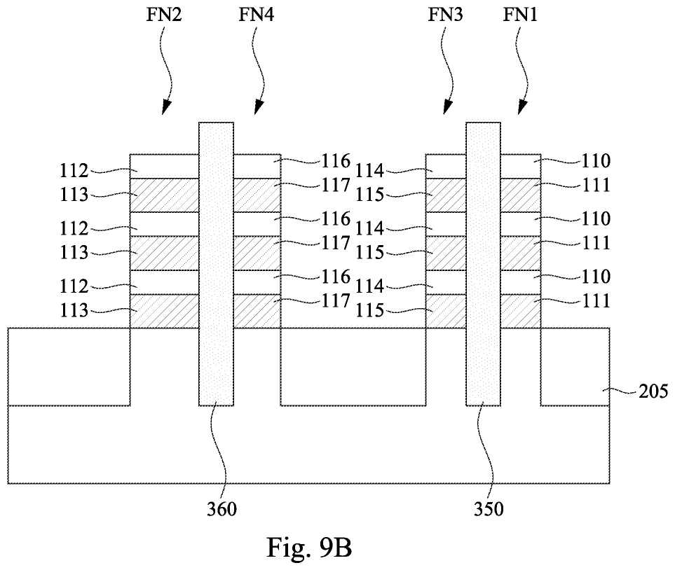

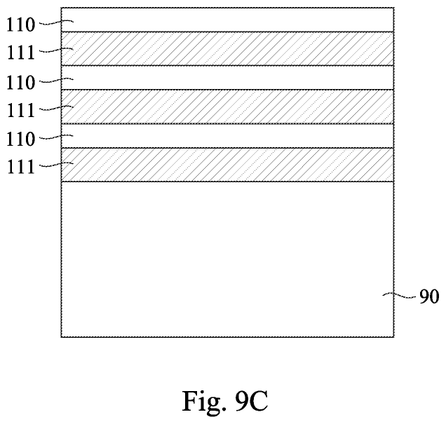

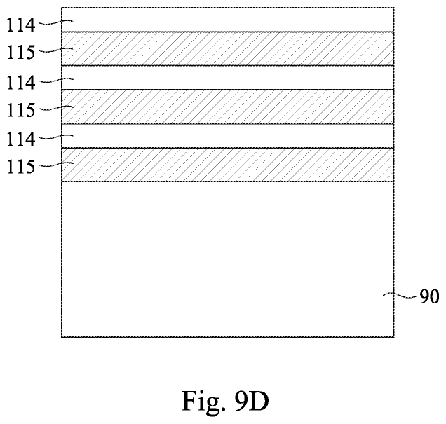

Reference is made to FIGS. 9A to 9D, in which FIGS. 9A to 9D follow the cross-sectional views of FIGS. 8A to 8D, respectively. A second etching process (e.g., etch back process) is performed to lower top surfaces of the isolation structures 205. In some embodiments, the first etching process may include dry etch, wet etch, or combinations thereof.

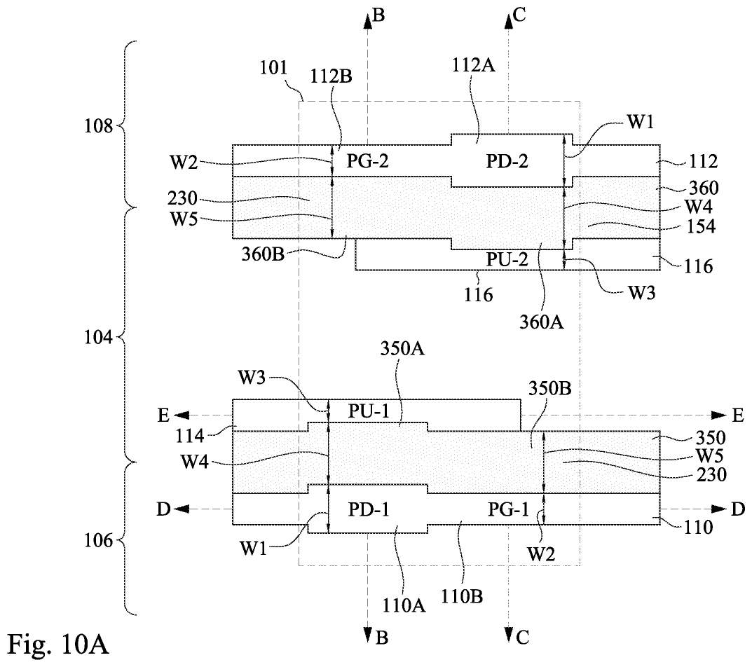

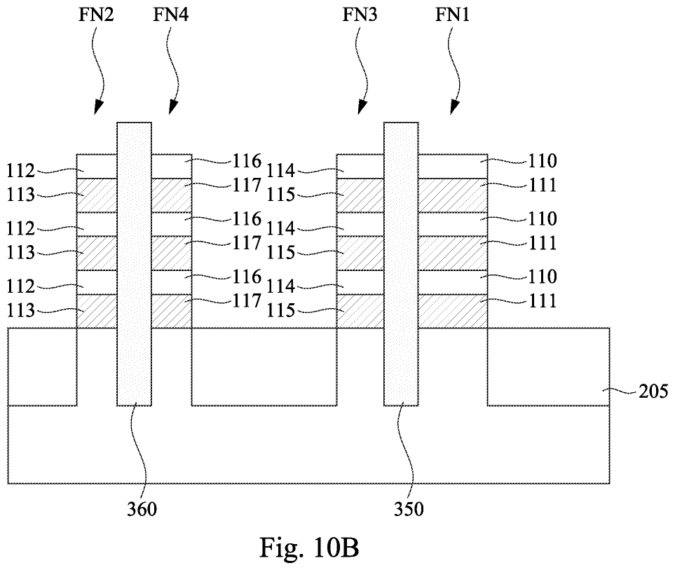

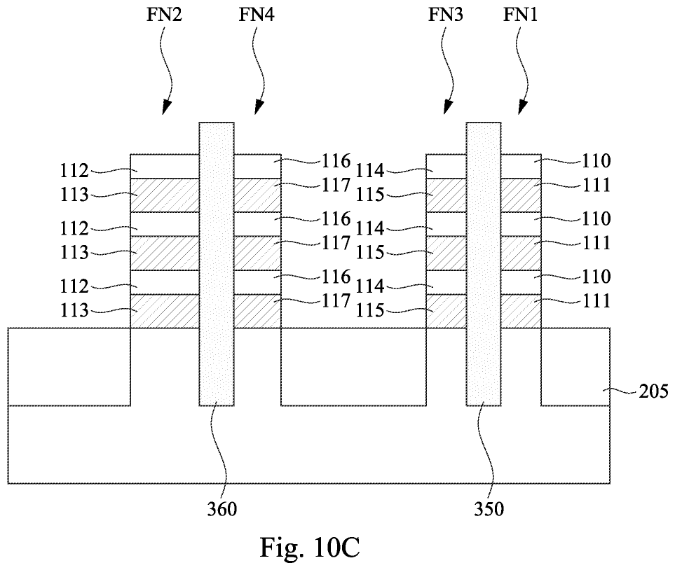

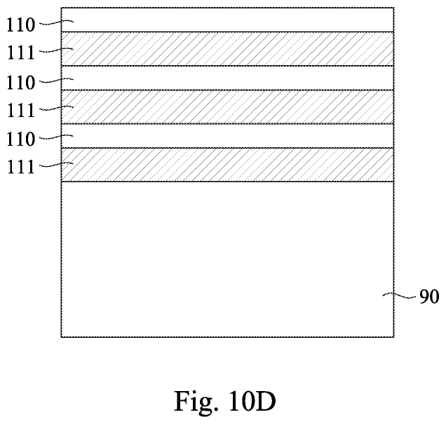

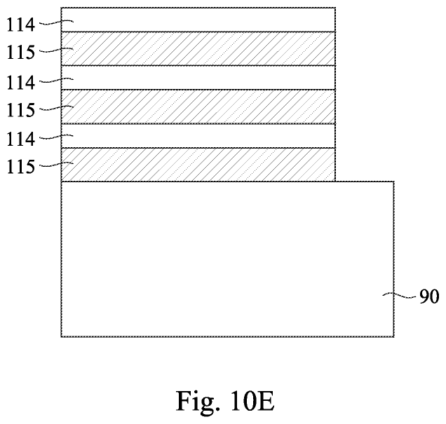

Reference is made to FIGS. 10A to 10E, in which FIG. 10A is a cell array layout diagram of an SRAM device, FIGS. 10B, 10C, 10D, and 10E are cross-sectional views along lines B-B, C-C, D-D, E-E of FIG. 10A, respectively. A patterning process is performed to remove portions of the fin structures FN3 and FN4. For example, portions of the semiconductor layers 114 and 115 of the fin structure FN3 are removed. Similarly, portions of the semiconductor layers 116 and 117 of the fin structure FN4 are removed. In some embodiments, the patterning process may be performed by, for example, forming a patterned mask over the substrate 90, the patterned mask having openings exposing portions of the fin structures FN3 and FN4. An etching process is performed to remove portions of the fin structures FN3 and FN4 exposed by the openings of the patterned mask. Afterwards, the patterned mask is removed.

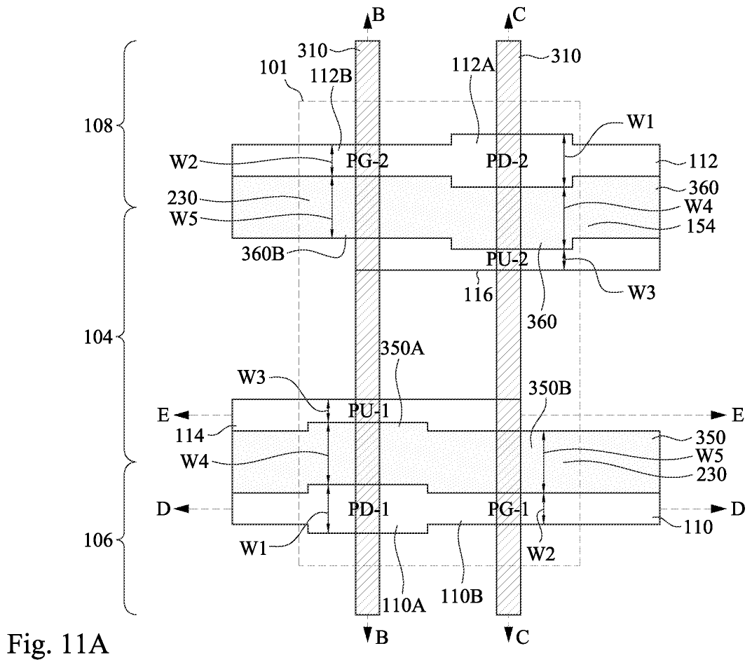

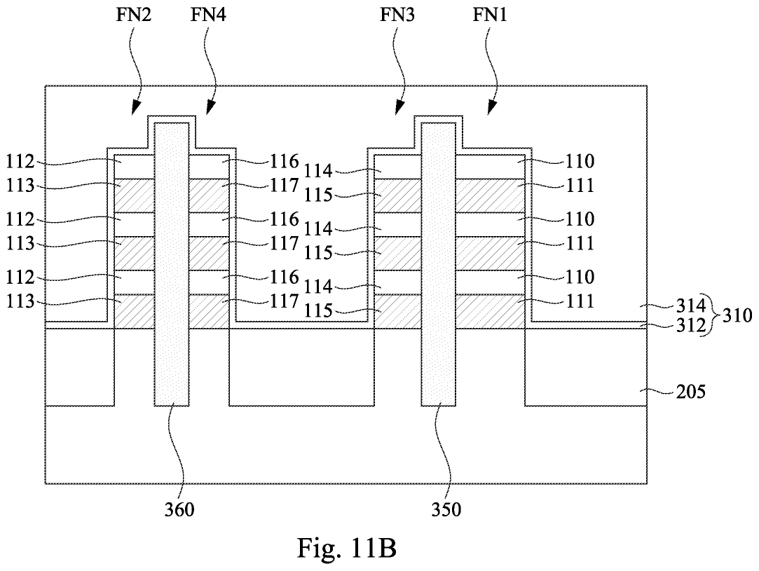

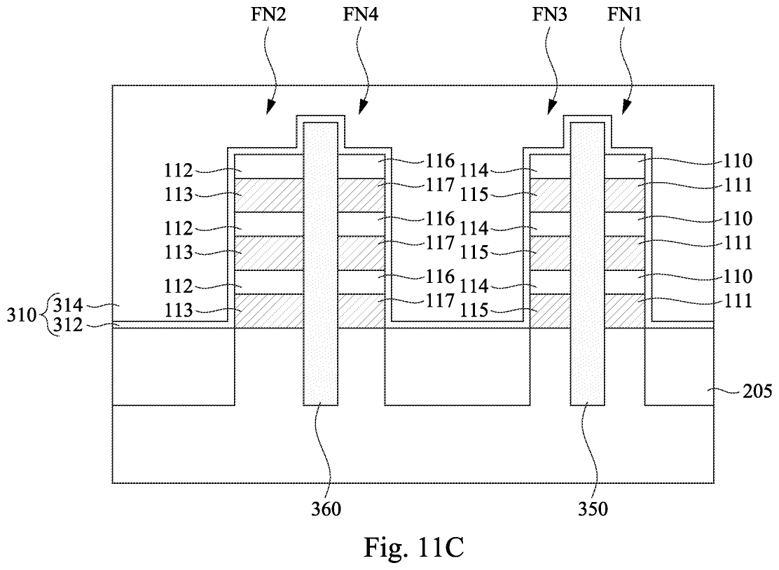

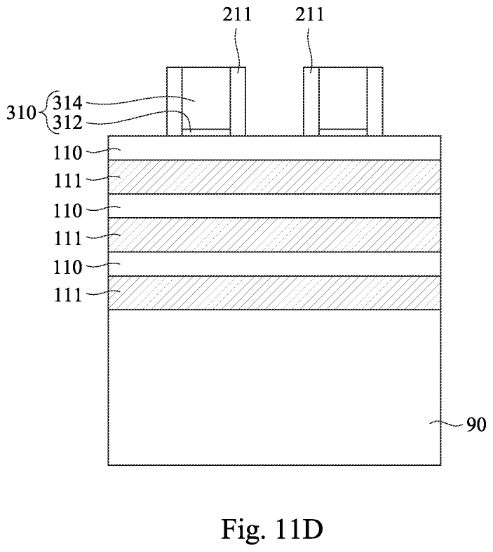

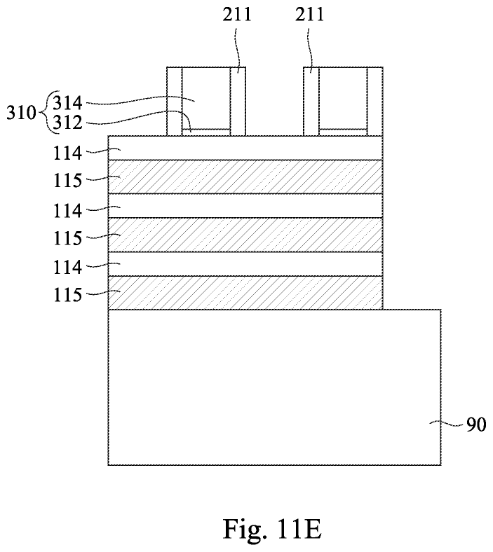

Reference is made to FIGS. 11A to 11E, in which FIG. 11A is a cell array layout diagram of an SRAM device, FIGS. 11B, 11C, 11D, and 11E are cross-sectional views along lines B-B, C-C, D-D, E-E of FIG. 11A, respectively. Dummy gate structures 310 are formed over the substrate 90 and crossing the fin structures FN1, FN2, FN3, and FN4. In some embodiments, each of the dummy gate structures 310 includes a gate dielectric 312 and a gate electrode 314 over the gate dielectric 312. The gate dielectric 312 may include one or more dielectric layers, such as an oxide, a metal oxide, the like, or combinations thereof. For example, in some embodiments, the gate dielectrics may include a silicon oxide layer and a metal oxide layer over the silicon oxide layer. The gate electrode 314 may be formed, for example, using polysilicon, although other materials such as metal silicides, metal nitrides, or the like, may also be used.

Gate spacers 211 are formed on opposite sidewalls of the dummy gate structures 310. That gate spacers 211 may be formed by, for example, depositing a dielectric layer blanket over the substrate 90, and then performing an anisotropic etching process to remove horizontal portions of the dielectric layer, while leaving vertical portions of the dielectric layer on opposite sidewalls of the dummy gate structures 310.

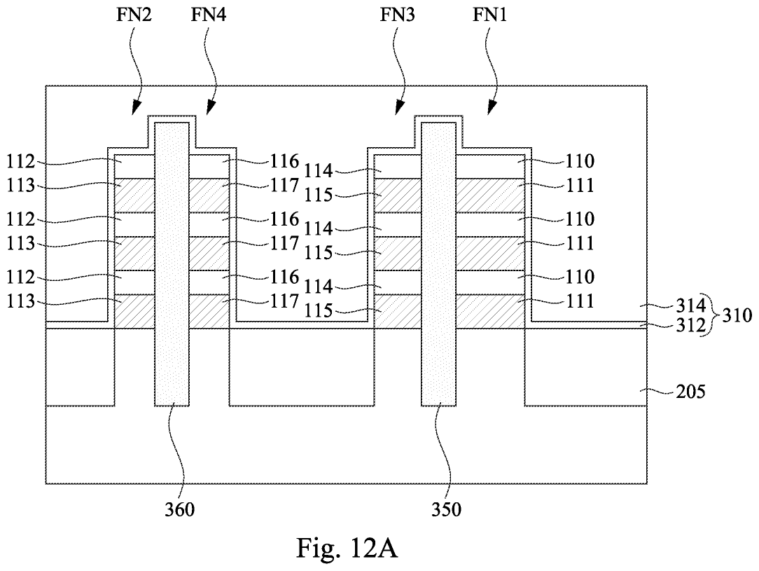

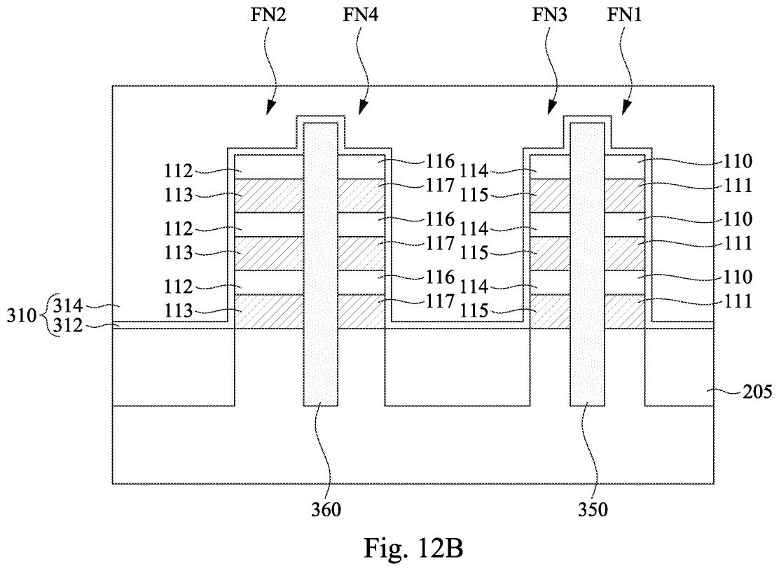

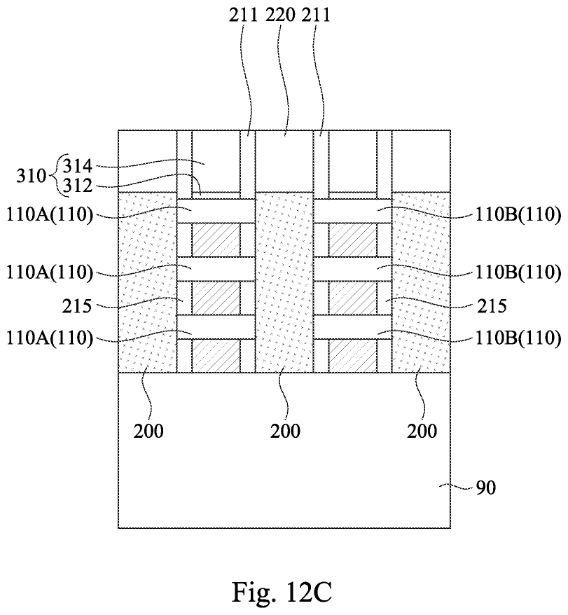

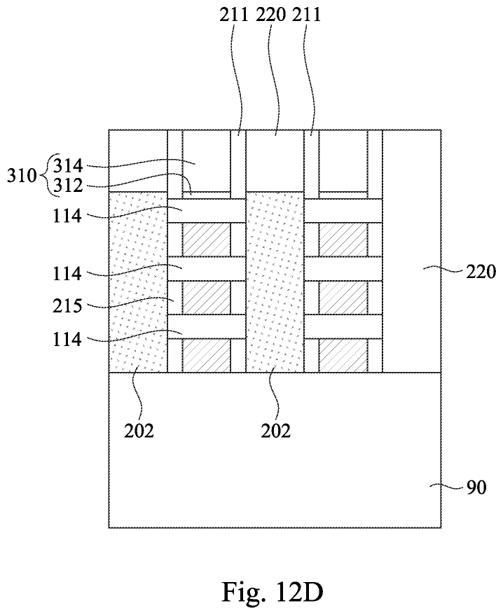

Reference is made to FIGS. 12A to 12D, in which FIGS. 12A to 12D follow the cross-sectional views of FIGS. 11B to 11E, respectively. Portions of the exposed semiconductor layers 111, 113, 114, 115 are laterally etched to form sidewall recesses, and then inner spacers 215 are formed in the sidewall recesses. In some embodiments, the sidewalls of the semiconductor layers 111, 113, 114, 115 may be etched using isotropic etching processes, such as wet etching or the like. In some embodiments in which the semiconductor layers 111, 113, 114, 115 include, e.g., SiGe, and the semiconductor layers 110, 112, 114, 116 include, e.g., Si, a dry etch process with tetramethylammonium hydroxide (TMAH), ammonium hydroxide (NH₄OH), or the like may be used to etch sidewalls of the semiconductor layers 111, 113, 114, 115.

The inner spacers 215 may be deposited by a conformal deposition process, such as CVD, ALD, or the like. The inner spacers 215 may be formed by, for example, depositing an inner spacer layer blanket over the substrate 90 and filling the sidewall recesses of the semiconductor layers 111, 113, 114, 115, and then performing an anisotropic etching to remove unwanted portions of the inner spacer layer.

Source/drain epitaxy structures 200 and 202 are formed over the substrate 90 and on opposite sides of each of the dummy gate structures 310, respectively. In some embodiments, the source/drain epitaxy structures 200 and 202 may be formed by, for example, performing a deposition process, such as an epitaxial growth, to grow an epitaxial material over the substrate 90.

After the source/drain epitaxy structures 200 and 202 are formed, interlayer dielectric (ILD) layer 220 are formed covering the source/drain epitaxy structures 200 and 202, and laterally surrounding the dummy gate structures 310. In some embodiments, the ILD layer 220 may be formed by, for example depositing a dielectric material over the substrate 90, and then performing a planarization process (e.g., a CMP process) until top surfaces of the dummy gate structures 310 are exposed.

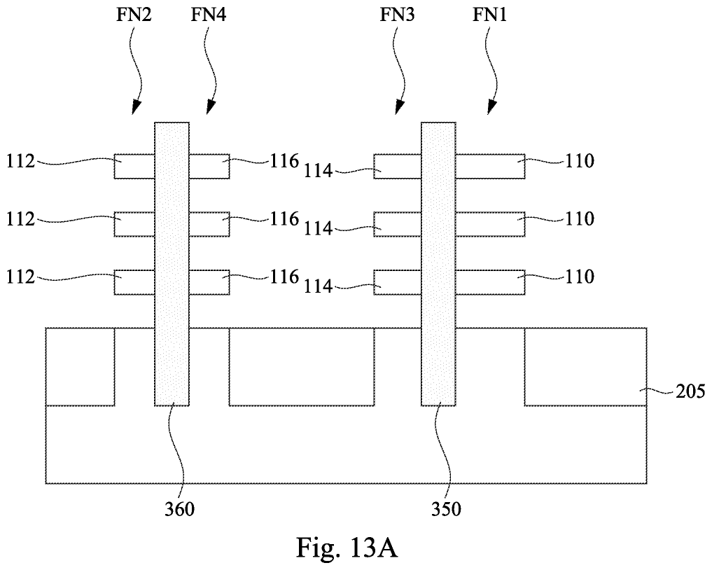

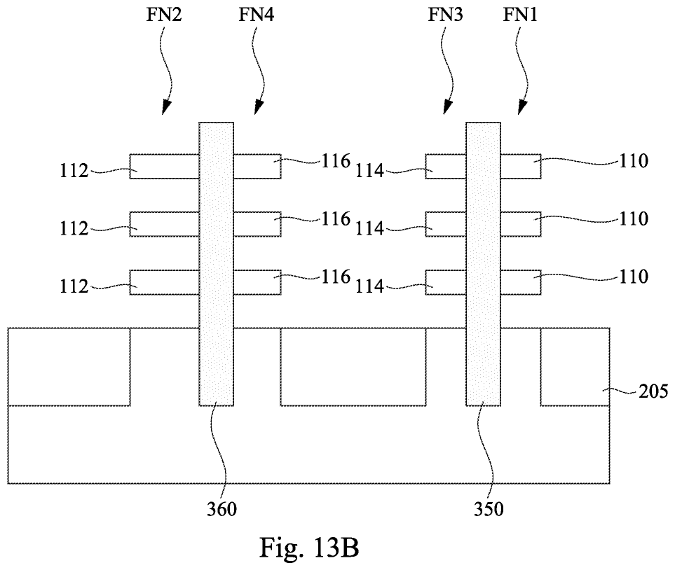

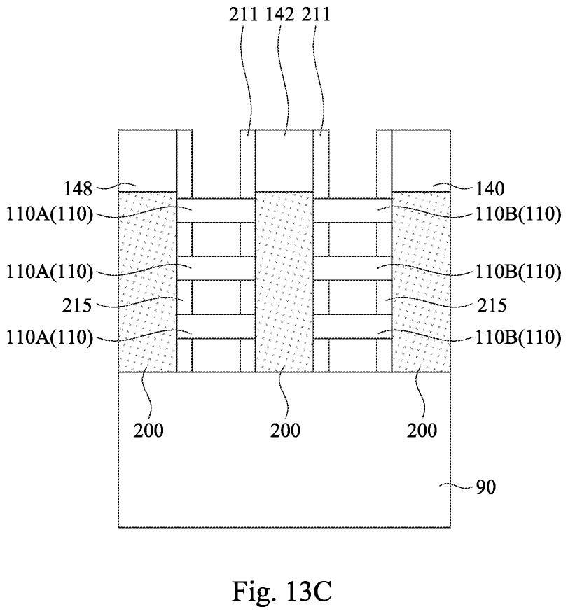

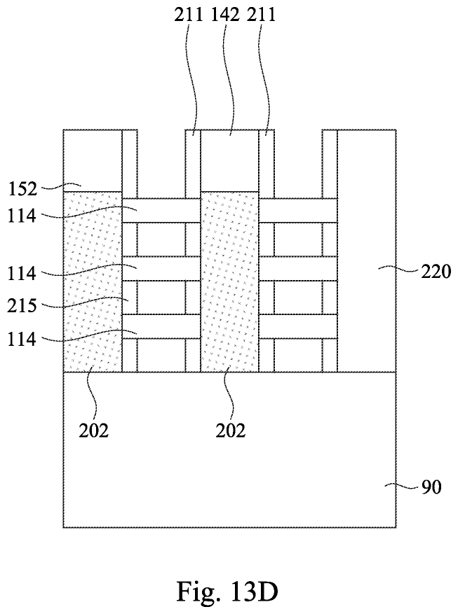

Reference is made to FIGS. 13A to 13D, in which FIGS. 13A to 13D follow the cross-sectional views of FIGS. 12A to 12D, respectively. The dummy gate structures 310 are removed to form gate trenches. In some embodiments, the dummy gate structures 310 may be removed by suitable etching process, such as dry etch, wet etch, or combinations thereof. Next, the semiconductor layers 111, 113, 115, and 117 are removed through the gate trenches, such that portions of the semiconductor layers 110, 112, 114, and 116 are suspended over the substrate 90. The semiconductor layers 111, 113, 115, and 117 may be removed by performing an isotropic etching process such as wet etching or the like using etchants which are selective to the materials of the semiconductor layers 111, 113, 115, and 117, while the semiconductor layers 110, 112, 114, and 116 remain relatively un-etched as compared to the semiconductor layers 111, 113, 115, and 117. In embodiments where the semiconductor layers 111, 113, 115, and 117 include, e.g., SiGe, and the semiconductor layers 110, 112, 114, and 116 include, e.g., Si, tetramethylammonium hydroxide (TMAH), ammonium hydroxide (NH₄OH), or the like may be used to remove the semiconductor layers 111, 113, 115, and 117.

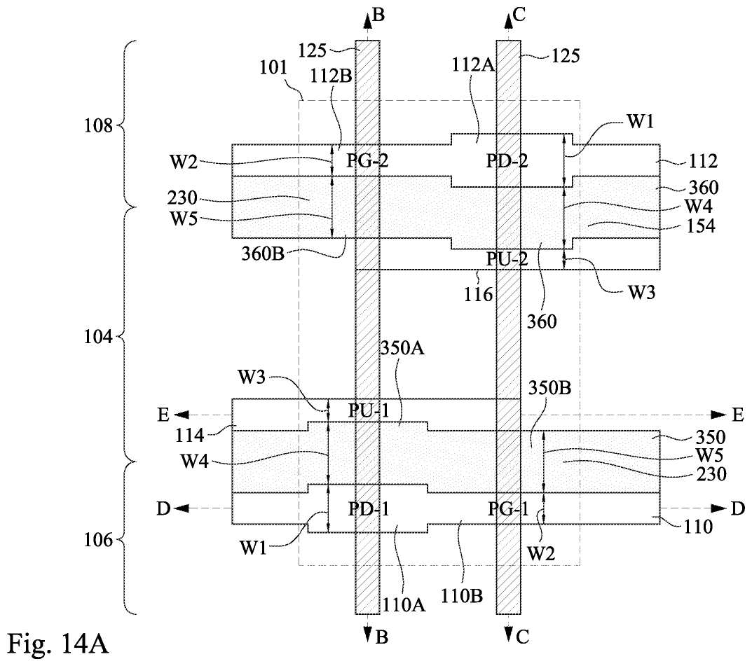

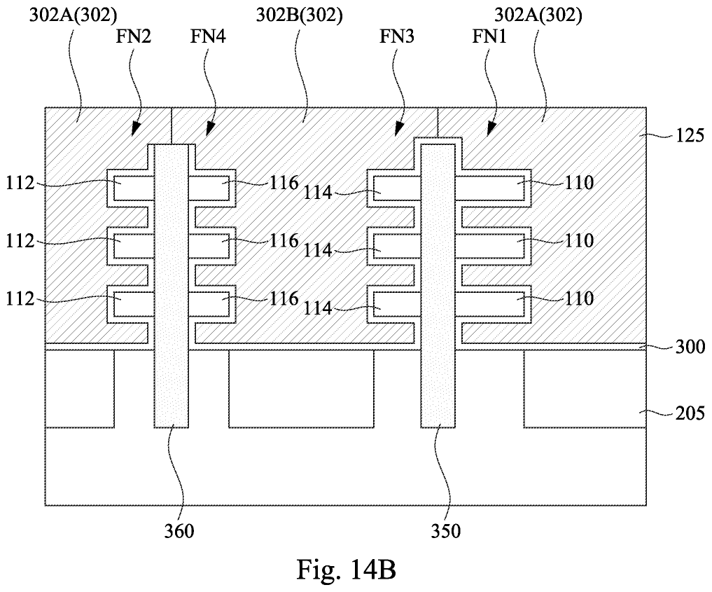

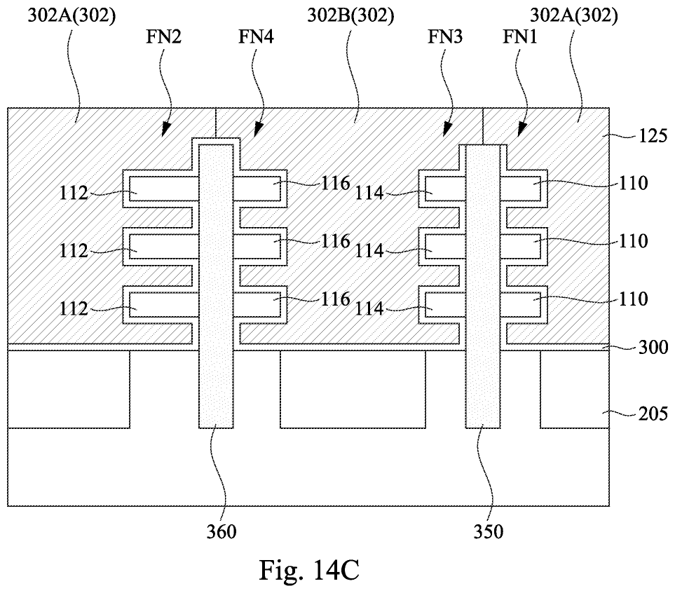

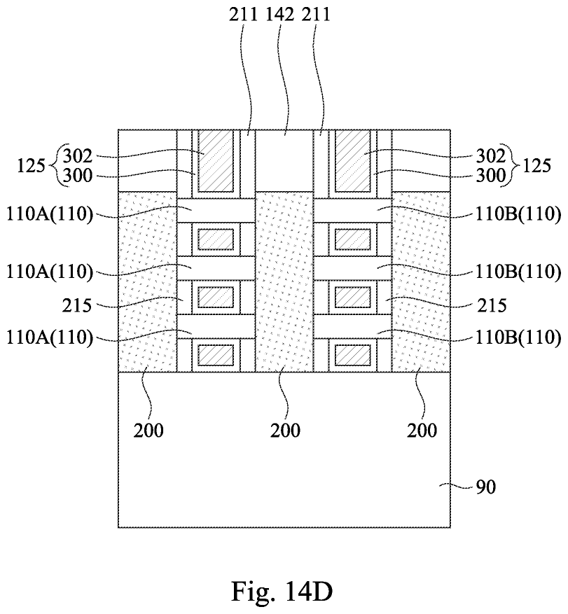

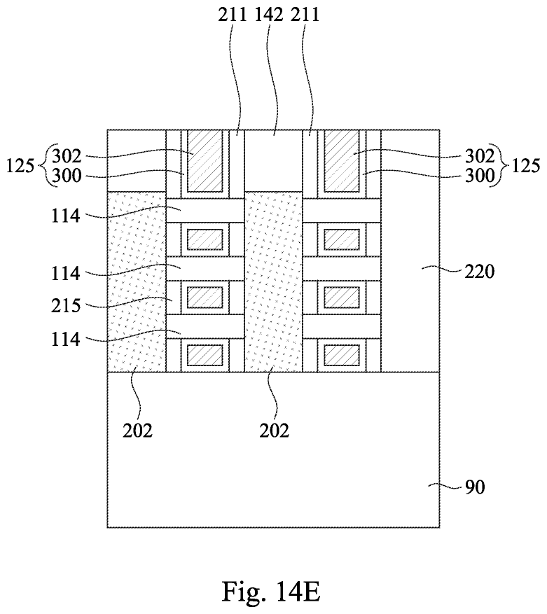

Reference is made to FIGS. 14A to 14E, in which FIG. 14A is a cell array layout diagram of an SRAM device, FIGS. 14B, 14C, 14D, and 14E are cross-sectional views along lines B-B, C-C, D-D, E-E of FIG. 14A, respectively. Gate structures 125 are formed in the gate trenches and wrapping around each of the semiconductor layers 110, 112, 114, and 116. In some embodiments, a gate dielectric 300 is conformally deposited over the substrate 90 and wrapping around each of the semiconductor layers 110, 112, 114, and 116, and then a gate electrode 302 is deposited over the gate dielectric 300 and overfilling the gate trenches. After the filling of the gate trenches, a planarization process, such as a CMP, may be performed to remove the excess portions of the gate dielectric 300 and the material of the gate electrode 302, which excess portions are over the top surface of the ILD layer 220. The remaining portions of material of the gate dielectric 300 and the gate electrode 302 thus form replacement gate structures 118, 120, 122, and 124.

In some embodiments, the gate electrode 302 may include a gate electrode 302A and a gate electrode 302B. In such embodiments, the gate electrode 302A may be deposited first, and the gate electrode 302B is formed after the gate electrode 302A. Alternatively, the gate electrode 302B may be deposited first, and the gate electrode 302B is formed after the gate electrode 302B.

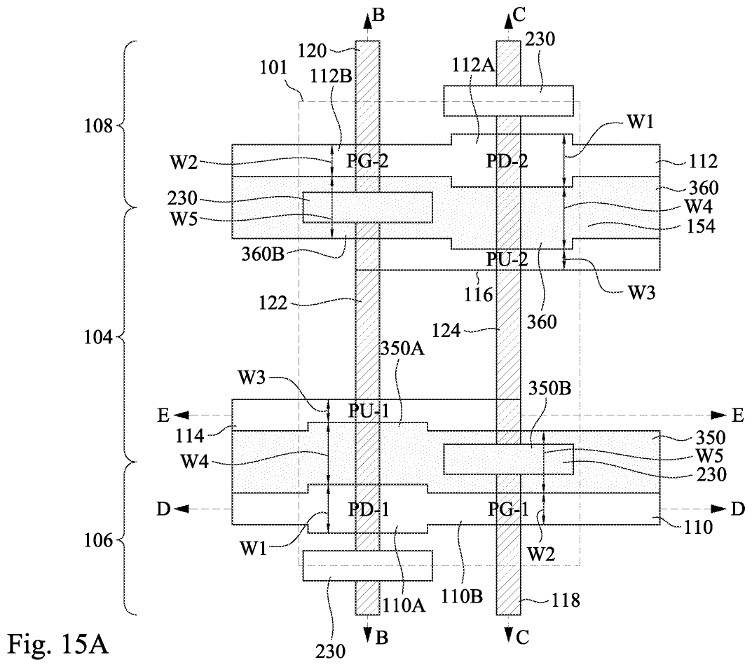

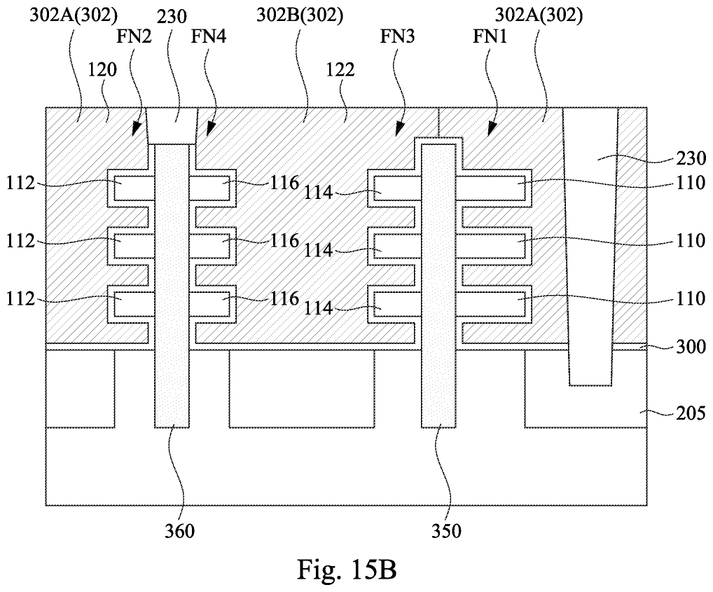

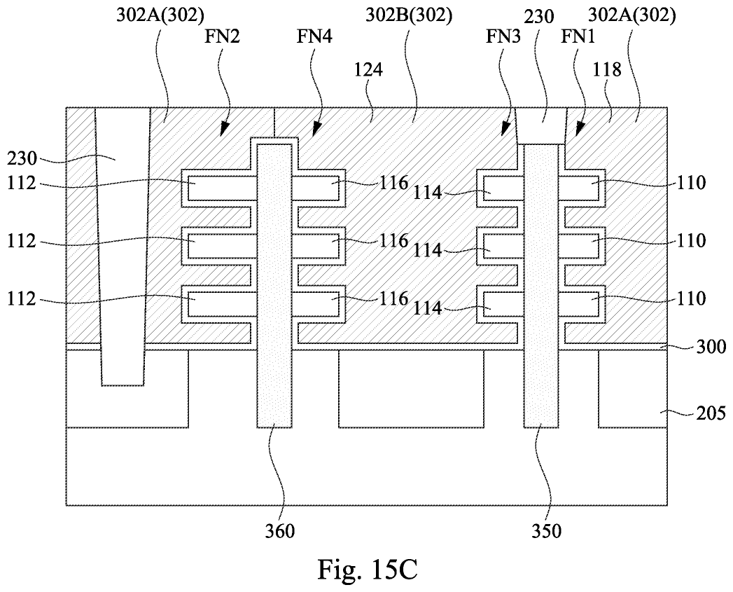

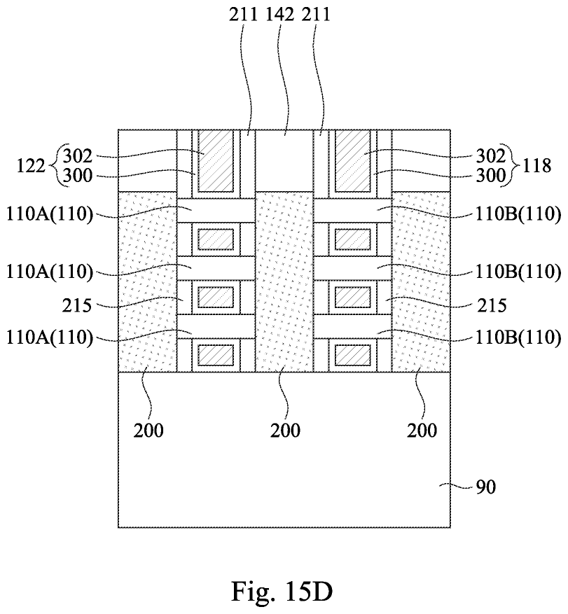

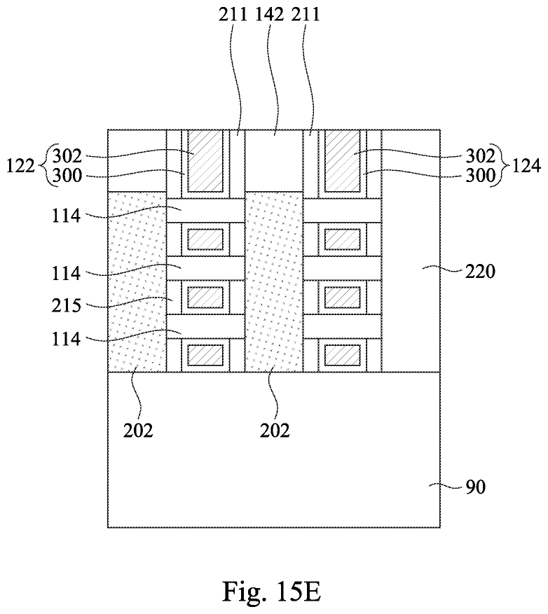

Reference is made to FIGS. 15A to 15E, in which FIG. 15A is a cell array layout diagram of an SRAM device, FIGS. 15B, 15C, 15D, and 15E are cross-sectional views along lines B-B, C-C, D-D, E-E of FIG. 15A, respectively. Gate-cut dielectric structures 230 are formed, such that the gate structures 125 are divided into separated gate structures 118, 120, 122, and 124, respectively. In some embodiments, the gate-cut dielectric structures 230 may be formed by, for example, patterning the gate structures 125 and the ILD layer 220 to form openings, depositing a dielectric material in the openings, and then performing a planarization process (e.g., a CMP process) to remove excess dielectric material until top surfaces of the gate structures 125 and the ILD layer 220 are exposed.

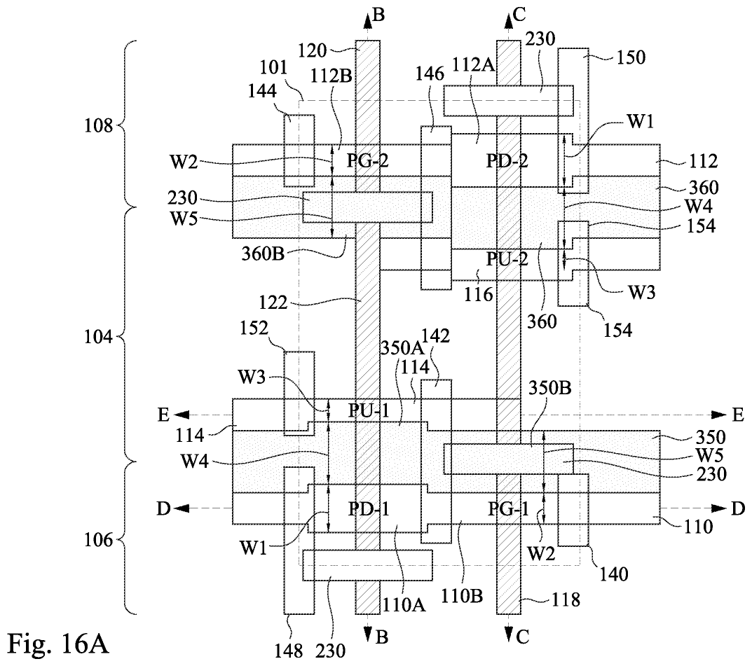

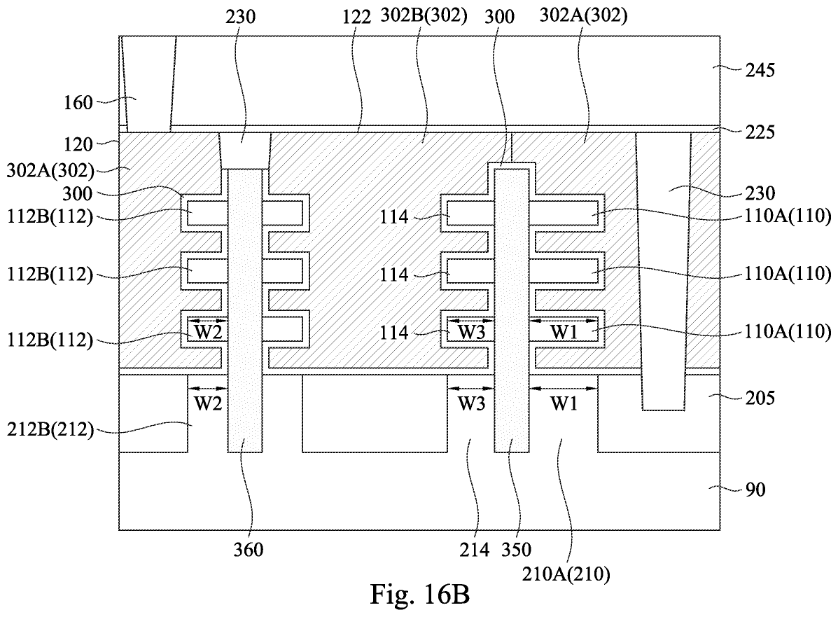

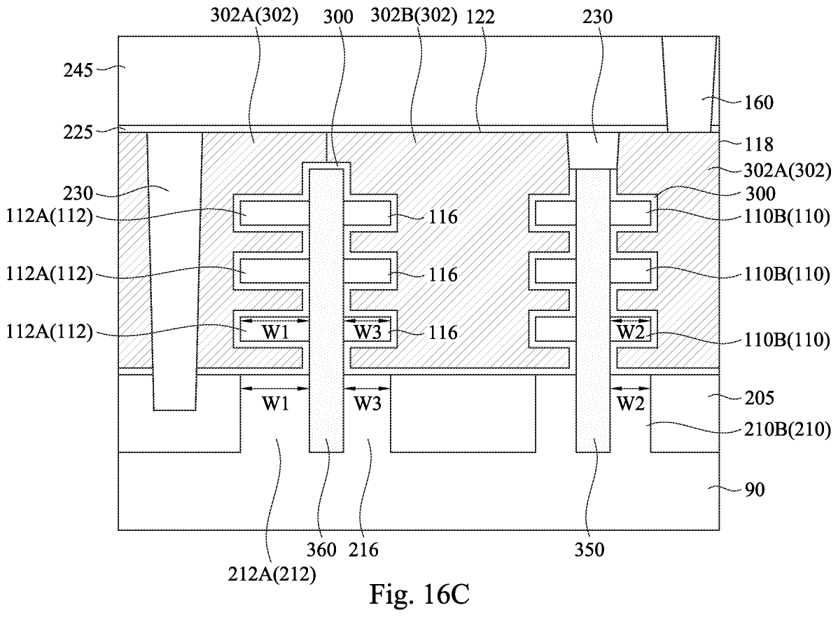

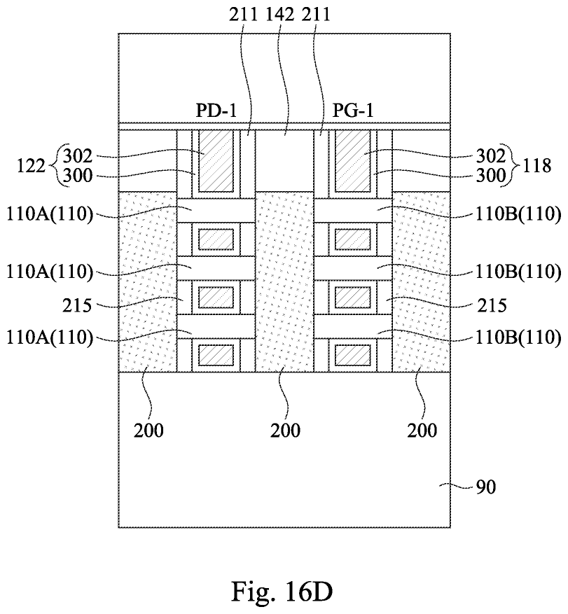

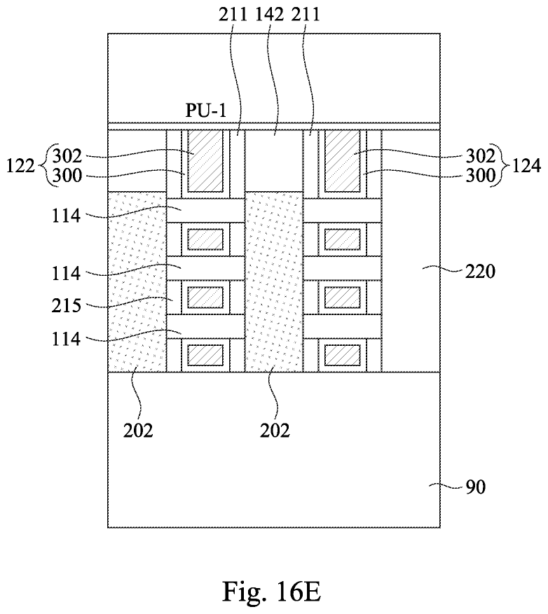

Reference is made to FIGS. 16A to 16E, in which FIG. 16A is a cell array layout diagram of an SRAM device, FIGS. 16B, 16C, 16D, and 16E are cross-sectional views along lines B-B, C-C, D-D, E-E of FIG. 16A, respectively. Source/drain contacts 140, 142, 144, 146, 152, and 154 are formed. In some embodiments, the source/drain contacts 140, 142,144, 146, 152, and 154 may be formed by, for example, patterning the ILD layer 220 to form openings exposing the source/drain epitaxy structures 200 and 202, depositing a contact material in the openings, and then performing a planarization process (e.g., a CMP process) to remove excess contact material until top surfaces of the ILD layer 220 and the gate-cut dielectric structures 230 are exposed.

Etch stop layer (ESL) 225 is formed covering the top surface of each of the gate structures 118, 120, 122, and 124, and then an interlayer dielectric (ILD) layer 245 is formed over the ESL 225. The ESL 225 and the ILD layer 245 may be formed by suitable deposition process, such as CVD, ALD, PVD, or the like.

Then, vias 160 are formed in the ESL 225 and the ILD layer 245. The vias 160 may be formed by, for example, patterning the ILD layer 245 and the ESL 225 to form openings, depositing via material in the openings, and then performing a planarization process (e.g., a CMP process) to remove excess via material until top surface of the ILD layer 245 is exposed.

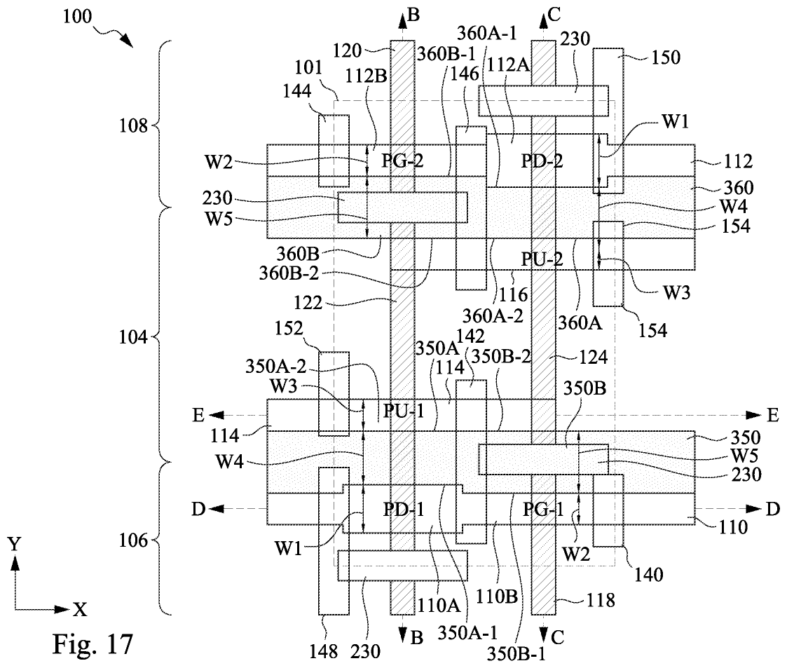

FIG. 17 illustrates a cell array layout diagram of an SRAM device according to some embodiments of the present disclosure. It is noted that some elements described in FIG. 17 are similar to or the same as those described in FIGS. 2A to 2E, such elements are labeled the same, and relevant details will not be repeated for brevity.

The differences between FIG. 17 and FIG. 2A include the top profiles of the semiconductor layers 114 and 116, and the top profiles of the dielectric walls 350 and 360. With respect to the semiconductor layers 114, the width W3 of the semiconductor layers 114 may be substantially equal to the width W2 of the semiconductor layers 110B. With respect to the semiconductor layers 116, the width W3 of the semiconductor layers 116 may be substantially equal to the width W2 of the semiconductor layers 112B.

With respect to the dielectric wall 350, the width W4 of the first portion 350A of the dielectric wall 350 may be less than the width W5 of the second portion 350B of the dielectric wall 350. In some embodiments, the dielectric wall 350 may include a stepped sidewall and a linear sidewall opposite to the stepped sidewall. Stated another way, a sidewall of the first portion 350A of the dielectric wall 350 may be aligned with a sidewall of the second portion 350B of the dielectric wall 350, while another sidewall of the first portion 350A of the dielectric wall 350 may be misaligned with another sidewall of the second portion 350B of the dielectric wall 350.

With respect to the dielectric wall 360, the width W4 of the first portion 360A of the dielectric wall 360 may be less than the width W5 of the second portion 360B of the dielectric wall 360. In some embodiments, the dielectric wall 360 may include a stepped sidewall and a linear sidewall opposite to the stepped sidewall. Stated another way, a sidewall of the first portion 360A of the dielectric wall 360 may be aligned with a sidewall of the second portion 360B of the dielectric wall 360, while another sidewall of the first portion 360A of the dielectric wall 360 may be misaligned with another sidewall of the second portion 360B of the dielectric wall 360.

The structure of FIG. 17 can be obtained by, for example, during forming the fin structures FN1 to FN4 as described in FIG. 4A, the semiconductor layers 114 and 116 are patterned to have a uniform width along the Y-direction. That is, the semiconductor layers 114 and 116 each may include linear opposite sidewalls. The dielectric walls 350 and 360 can be formed having such top profiles according to the shapes of the semiconductor layers 110, 112, 114, and 116.

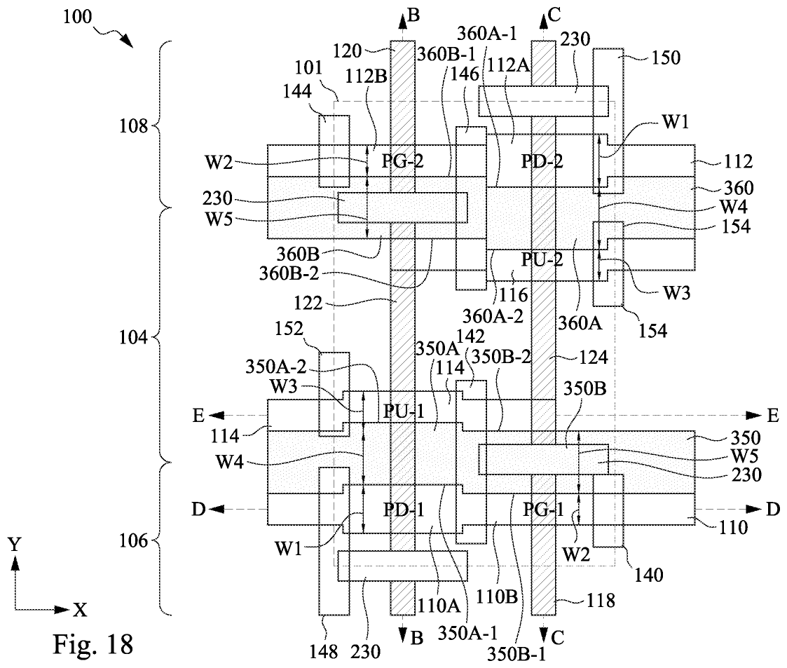

FIG. 18 illustrates a cell array layout diagram of an SRAM device according to some embodiments of the present disclosure. It is noted that some elements described in FIG. 18 are similar to or the same as those described in FIGS. 2A to 2E, such elements are labeled the same, and relevant details will not be repeated for brevity.

The differences between FIG. 18 and FIG. 2A include the top profiles of the semiconductor layers 114 and 116. With respect to the semiconductor layers 114, the width W3 of the semiconductor layers 114 may be substantially equal to the width W2 of the semiconductor layers 110B. With respect to the semiconductor layers 116, the width W3 of the semiconductor layers 116 may be substantially equal to the width W2 of the semiconductor layers 112B.

The structure of FIG. 18 can be obtained by, for example, during forming the fin structures FN1 to FN4 as described in FIG. 4A, the semiconductor layers 114 and 116 are patterned to have stepped opposite sidewalls. For example, opposite sidewalls of the first portion 114A of each semiconductor layer 114 may be misaligned with opposite sidewalls of the second portion 114B of each semiconductor layers 114. In some embodiments, the width W3 of the first portion 114A of each semiconductor layer 114 may be substantially the same as the width W7 of the second portion 114A of each semiconductor layer 114. Similarly, opposite sidewalls of the first portion 116A of each semiconductor layer 116 may be misaligned with opposite sidewalls of the second portion 116B of each semiconductor layers 116. In some embodiments, the width W3 of the first portion 116A of each semiconductor layer 116 may be substantially the same as the width W7 of the second portion 116B of each semiconductor layer 116.

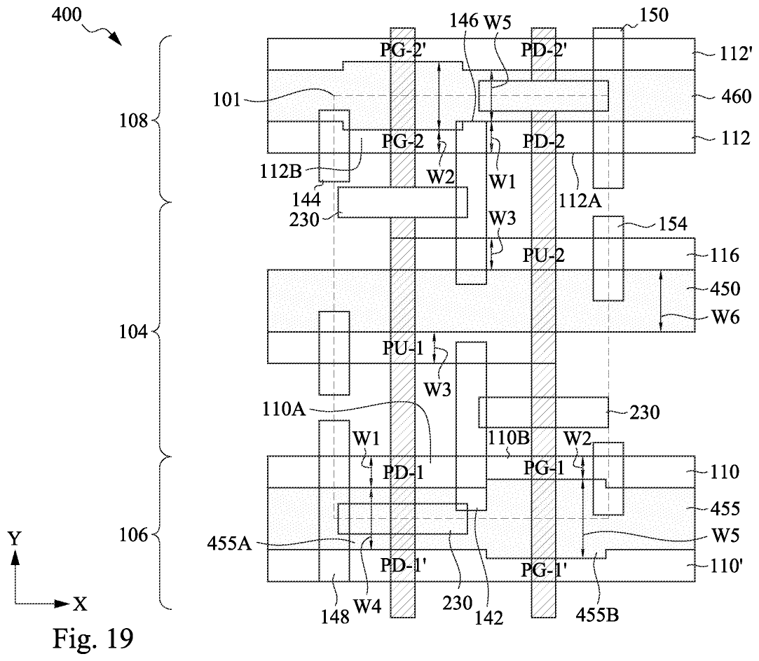

FIG. 19 illustrates a cell array layout diagram of an SRAM device according to some embodiments of the present disclosure. It is noted that some elements described in FIG. 19 are similar to or the same as those described in FIGS. 2A to 2E, such elements are labeled the same, and relevant details will not be repeated for brevity.

FIG. 19 is different from FIG. 2A, in that the SRAM device 400 of FIG. 19 includes dielectric walls 450, 455, and 460. Materials of the dielectric walls 450, 455, and 460 may be similar to the dielectric walls 350 and 360 described with respect to FIGS. 2A to 2E. The dielectric wall 450 is laterally between the PU-1 transistor and the PU-2 transistor. In greater details, the dielectric wall 450 is laterally between and in contact with the semiconductor layers 114 and 116. The dielectric wall 455 is laterally between the PD-1 transistor (or the PG-1 transistor) and a PD-1′ transistor (or a PG-1′ transistor). In greater details, the dielectric wall 455 is laterally between and in contact with the semiconductor layers 110 and 110′. Here, the PD-1′ transistor and the PG-1′ transistor are transistors of another SRAM cell adjacent to the SRAM cell 101, which include similar configurations as the PD-1 transistor and the PG-1 transistor. The dielectric wall 460 is laterally between the PD-2 transistor (or the PG-2 transistor) and a PD-2′ transistor (or a PG-2′ transistor). In greater details, the dielectric wall 460 is laterally between and in contact with the semiconductor layers 112 and 112′. Here, the PD-2′ transistor and the PG-2′ transistor are transistors of another SRAM cell adjacent to the SRAM cell 101, which include similar configurations as the PD-2 transistor and the PG-2 transistor.

The semiconductor layers 110 may include first portions 110A and second portions 110B. Similarly, the semiconductor layers 112 may include first portions 112A and second portions 112B. The semiconductor layers 110A have a width W1 along the Y-direction, the semiconductor layers 110B have a width W2 along the Y-direction, and the semiconductor layers 114 have a width W3 along the Y-direction. Similarly, the semiconductor layers 112A have a width W1 along the Y-direction, the semiconductor layers 112B have a width W2 along the Y-direction, and the semiconductor layers 116 have a width W3 along the Y-direction.

In some embodiments, the width W1 is greater than the width W2, and the width W2 is substantially equal to the width W3. In some embodiments, a sidewall of the semiconductor layer 110 has a stepped sidewall profile, while another sidewall of the semiconductor layer 110 has a linear sidewall profile. In some embodiments, a sidewall of the semiconductor layer 112 has a stepped sidewall profile, while another sidewall of the semiconductor layer 112 has a linear sidewall profile. In some embodiments, opposite sidewalls of the semiconductor layers 114 have linear sidewall profile, and opposite sidewalls of the semiconductor layers 116 have linear sidewall profile. The top profiles of the semiconductor layers 110′ and 112′ are the same as the semiconductor layers 110 and 112, respectively, and thus relevant details will not be repeated for brevity.

The dielectric wall 450 has a width W6 along the Y-direction. In some embodiments, opposite sidewalls of the dielectric wall 450 each has a linear sidewall profile. That is, the dielectric wall 450 may include a uniform width.

The dielectric wall 455 has a first portion 455A and a second portion 455B connected to the first portion 455A. The first portion 455A has a width W4 along the Y-direction, and the second portion 455B has a width W5 along the Y-direction. In some embodiments, the width W4 is less than the width W5. In some embodiments, opposite sidewalls of the dielectric wall 455 both include a stepped sidewall profile.

The structure shown in FIG. 19 can be formed using a similar manner as the structure of FIG. 2A. For example, the profiles of the semiconductor layers 110, 112, 114, 116, 110′, and 112′ can be formed using the patterning process as described in FIGS. 4A to 4E. Moreover, after forming the dielectric film 340 (see FIGS. 5A to 5D), a photolithography process is performed to remove unwanted portions of the dielectric film 340, and the remaining portions of the dielectric film 340 may serve as the dielectric walls 450, 455, and 460 as shown in FIG. 19.

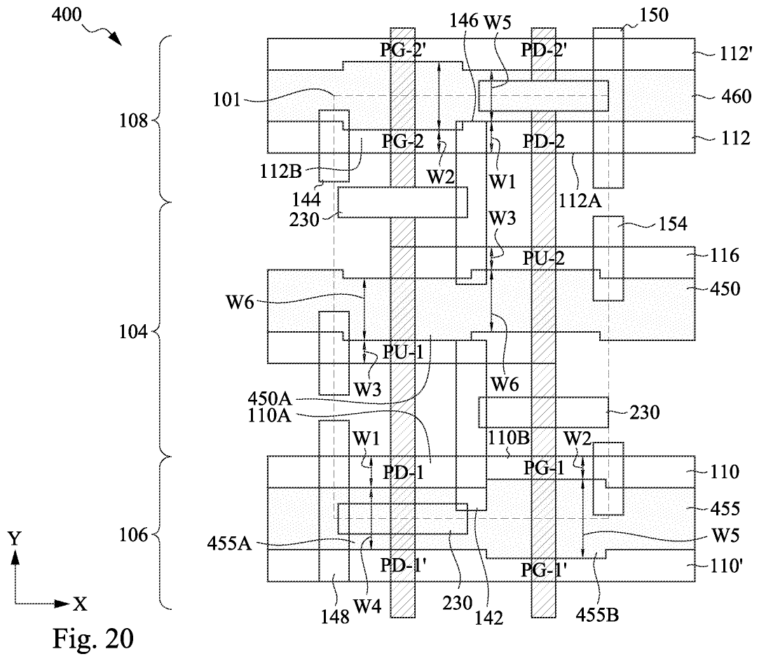

FIG. 20 illustrates a cell array layout diagram of an SRAM device according to some embodiments of the present disclosure. It is noted that some elements described in FIG. 20 are similar to or the same as those described in FIGS. 2A to 2E and FIG. 19, such elements are labeled the same, and relevant details will not be repeated for brevity.

FIG. 20 is different from FIG. 19, in that the width W3 of the semiconductor layers 114 and 116 is less than the width W2 of the semiconductor layers 110B. Moreover, the dielectric wall 450 includes a first portion 450A and a second portion 450B connected to the first portion 450A. The first portion 450A and the second portion 450B both include a width W6. However, opposite sidewalls of the first portion 450A are misaligned with opposite sidewalls of the second portion 450B. That is, opposite sidewalls of the dielectric wall 450 both include a stepped sidewall profile.

The structure shown in FIG. 20 can be formed using a similar manner as the structure of FIG. 2A. For example, the profiles of the semiconductor layers 110, 112, 114, 116, 110′, and 112′ can be formed using the patterning process as described in FIGS. 4A to 4E. Moreover, after forming the dielectric film 340 (see FIGS. 5A to 5D), a photolithography process is performed to remove unwanted portions of the dielectric film 340, and the remaining portions of the dielectric film 340 may serve as the dielectric walls 450, 455, and 460 as shown in FIG. 20.

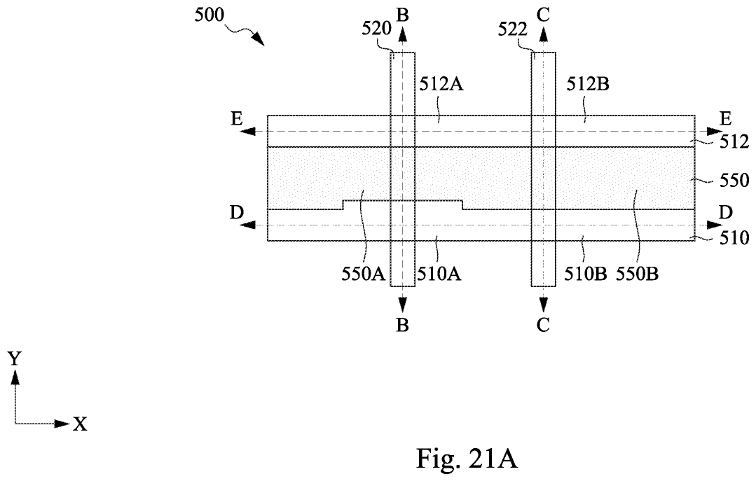

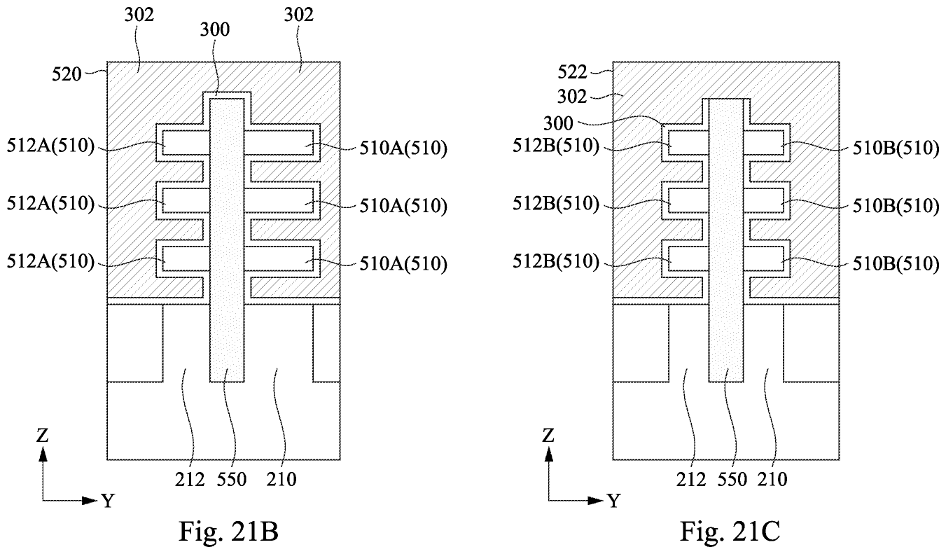

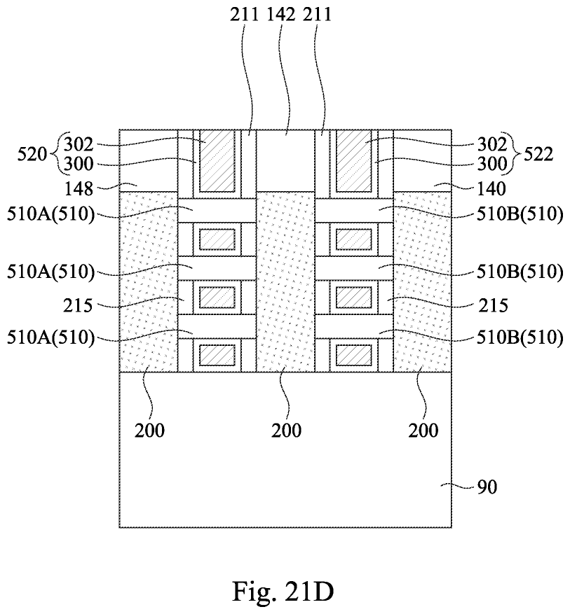

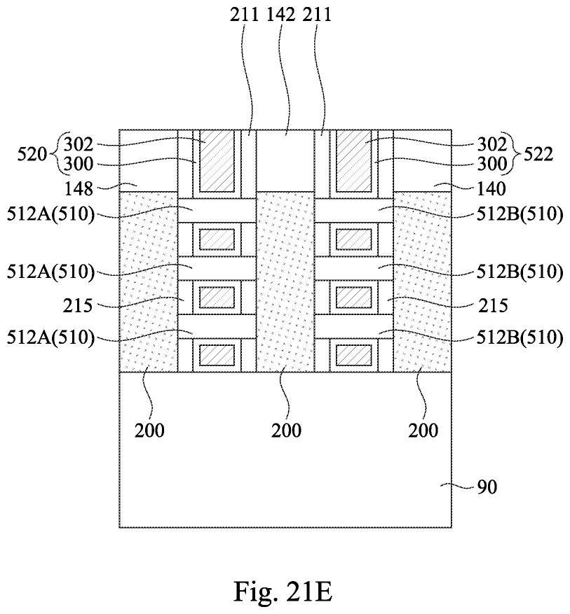

Reference is made to FIGS. 21A to 21E. FIG. 21A illustrates a layout diagram of a semiconductor device according to some embodiments of the present disclosure. In some embodiments, FIG. 21A is a top view (plane view) of a semiconductor device. FIGS. 21B to 21E are cross-sectional views along lines B-B, C-C, D-D, and E-E of FIG. 21A, respectively. In greater details, FIGS. 21B and 21C are cross-sectional views along the Y-direction, and FIGS. 21D and 21E are cross-sectional views along the X-direction. It is noted that some elements of FIGS. 21A to 21E are similar to those described above with respect to FIGS. 2A to 2E, such elements are labeled the same, and relevant details will not be repeated for brevity.

The semiconductor device 500 of FIGS. 21A to 21E includes semiconductor layers 510 and semiconductor layers 512 extend along the X-direction. In some embodiments, the semiconductor layers 510 and 512 may be similar to the semiconductor layers 110, 112, 114, and 116 described above.

In the top view of FIG. 21A, the semiconductor layer 510 includes a first portion 510A and a second portion 510B. The first portion 510A and the second portion 510B can also be referred to as semiconductor layer 510A and semiconductor layer 510B. Similarly, the semiconductor layer 512 includes a first portion 512A and a second portion 512B. The first portion 512A and the second portion 512B can also be referred to as semiconductor layer 512A and semiconductor layer 512B.

In some embodiments, the semiconductor layer 510A is wider than the semiconductor layer 510B along the Y-direction. In some embodiments, a sidewall of the semiconductor layer 510A is misaligned with a sidewall of the semiconductor layer 510B, while another sidewall of the semiconductor layer 510A is aligned with another sidewall of the semiconductor layer 510B. In some embodiments, the semiconductor layers 512A and 512B have substantially a same width along the Y-direction. In some embodiments, the semiconductor layers 512A, 512B, and 510B have substantially a same width along the Y-direction.

The semiconductor device 500 includes a dielectric wall 550 between the semiconductor layers 510 and 512. In greater details, the dielectric wall 550 is in contact with the semiconductor layers 510A 510B, 512A, and 512B. The dielectric wall 550 includes a first portion 550A and a second portion 550B. The first portion 550A is narrower than the second portion 550B along the Y-direction. In some embodiments, a sidewall of the dielectric wall 550 has a linear sidewall profile, while another sidewall of the dielectric wall 550 has a stepped sidewall profile.

The semiconductor device 500 includes a gate structure 520 and a gate structure 522. The gate structure 520 is over the semiconductor layers 510A and 512B, and is in contact with at least three surfaces of each of the semiconductor layers 510A and 512A (see FIG. 21D). The gate structure 522 is over the semiconductor layers 510B and 512B, and is in contact with at least three surfaces of each of the semiconductor layers 510B and 512B (see FIG. 21D).

The semiconductor device 500 includes source/drain epitaxy structures 200 on opposite sides of the gate structure 520 and on opposite sides of the gate structure 522 (see FIGS. 21D and 21E). The gate structure 520, the semiconductor layers 510A, and the source/drain epitaxy structures 200 can collectively serve as a transistor. The gate structure 520, the semiconductor layers 512A, and the source/drain epitaxy structures 200 can collectively serve as a transistor. The gate structure 522, the semiconductor layers 510B, and the source/drain epitaxy structures 200 can collectively serve as a transistor. The gate structure 522, the semiconductor layers 512B, and the source/drain epitaxy structures 200 can collectively serve as a transistor.

The structure shown in FIGS. 21A to 21E can be formed using a similar manner as the structure of FIGS. 2A to 2E. For example, the profiles of the semiconductor layers 510A, 510B, 512A, and 512B can be formed using the patterning process as described in FIGS. 4A to 4E. The dielectric wall 550 can be formed using the processes as described in FIGS. 5A to 6E. The gate structures 520 and 522 can be formed using the processes as described in FIGS. 11A to 15E.

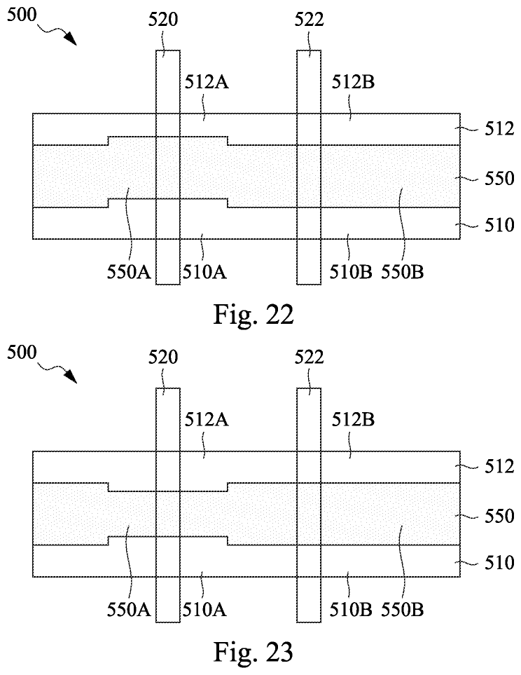

FIG. 22 illustrates a layout diagram of a semiconductor device according to some embodiments of the present disclosure. It is noted that some elements of FIG. 22 are similar to those described above with respect to FIGS. 21A to 21E, such elements are labeled the same, and relevant details will not be repeated for brevity.

FIG. 22 is different from FIG. 21A, in that the semiconductor layer 512A is narrower than the semiconductor layer 512B. Moreover, the first portion 550A of the dielectric wall 550 and the second portion 550B of the dielectric wall 550 have substantially a same width along the Y-direction. However, opposite sidewalls of the dielectric wall 550 both include a stepped sidewall profile.

FIG. 23 illustrates a layout diagram of a semiconductor device according to some embodiments of the present disclosure. It is noted that some elements of FIG. 23 are similar to those described above with respect to FIGS. 21A to 21E, such elements are labeled the same, and relevant details will not be repeated for brevity.

FIG. 23 is different from FIG. 21A, in that the semiconductor layer 512A is wider than the semiconductor layer 512B. Moreover, the first portion 550A of the dielectric wall 550 is narrower than the second portion 550B of the dielectric wall 550 along the Y-direction. However, opposite sidewalls of the dielectric wall 550 both include a stepped sidewall profile.

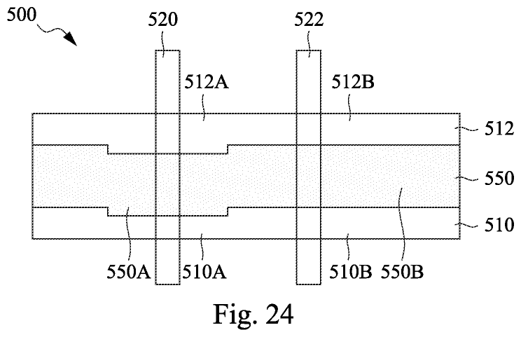

FIG. 24 illustrates a layout diagram of a semiconductor device according to some embodiments of the present disclosure. It is noted that some elements of FIG. 24 are similar to those described above with respect to FIGS. 21A to 21E, such elements are labeled the same, and relevant details will not be repeated for brevity.

FIG. 24 is different from FIG. 21A, in that the semiconductor layer 512A and the semiconductor layer 512B have substantially a same width along the Y-direction. Moreover, the first portion 550A of the dielectric wall 550 and the second portion 550B of the dielectric wall 550 have substantially a same width along the Y-direction. However, opposite sidewalls of the dielectric wall 550 both include a stepped sidewall profile.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a memory device, in which the PG-1, PG-2, PD-1, PD-2, PU-1, and PU-2 transistors of the memory device may include varied channel widths. Moreover, different portions of the dielectric walls of the memory device also include varied widths. Such configuration may optimize SRAM read/write margin, and thus the drain current of the PG-1, PG-2, PD-1, PD-2, PU-1, and PU-2 transistors can be improved.

In some embodiments of the present disclosure, a device includes a first transistor, a second transistor, and a dielectric wall. The first transistor includes a plurality of first semiconductor channel layers, a first gate structure over the plurality of first semiconductor channel layers, and first source/drain structures on opposite sides of the first gate structure. The second transistor includes a plurality of second semiconductor channel layers, a second gate structure over the plurality of second semiconductor channel layers, and second source/drain structures on opposite sides of the second gate structure. The dielectric wall includes a first sidewall abutting side surfaces of the plurality of first semiconductor channel layers in a first cross-sectional view taken along a longitudinal axis of the first gate structure, the first sidewall of the dielectric wall also abutting side surfaces of the plurality of second semiconductor channel layers in a second cross-sectional view taken along a longitudinal axis of the second gate structure, in which in a top view, the first sidewall of the dielectric wall has a stepped profile.

In some embodiments, in the top view, a second sidewall of the dielectric wall has a linear sidewall profile, the second sidewall being opposite to the first sidewall.

In some embodiments, in the top view, a second sidewall of the dielectric wall has a stepped profile, the second sidewall being opposite to the first sidewall.

In some embodiments, the dielectric wall further comprises second sidewall opposite the first sidewall, wherein a width between the first and second sidewalls under the first gate structure is less than a width between the first and second sidewalls under the second gate structure.

In some embodiments, the dielectric wall further comprises second sidewall opposite the first sidewall, wherein a width between the first and second sidewalls under the first gate structure is substantially equal to a width between the first and second sidewalls under the second gate structure.

In some embodiments, the plurality of first semiconductor channel layers are wider than the plurality of second semiconductor channel layers along a direction parallel to the longitudinal axis of the first gate structure.

In some embodiments, the device further includes a third transistor having a plurality of third semiconductor channel layers, a third gate structure over the plurality of third semiconductor channel layers, and third source/drain structures on opposite sides of the third gate structure. In the first cross-sectional view, a second sidewall of the dielectric wall is in contact with the plurality of third semiconductor channel layers, the second sidewall being opposite to the first sidewall.

In some embodiments, the plurality of first semiconductor channel layers are wider than the plurality of second semiconductor channel layers along a direction parallel to the longitudinal axis of the first gate structure, and the plurality of second semiconductor channel layers are wider than the plurality of third semiconductor channel layers along the direction.

In some embodiments of the present disclosure, a device includes a pull-down transistor, a pass-gate transistor, a pull-up transistor, and a dielectric wall. The pull-down transistor has a first semiconductor channel layer. The pass-gate transistor has a second semiconductor channel layer. The pull-up transistor has a third semiconductor channel layer. The pull-down transistor and the pass-gate transistor are arrange along a first direction, and the pull-down transistor and the pull-up transistor are arrange along a second direction perpendicular to the first direction, and the first semiconductor channel layer is wider than the second semiconductor channel layer along the second direction. The dielectric wall has a first sidewall and a second sidewall opposite to the first sidewall, in which the first sidewall is in contact with the first semiconductor channel layer and the second semiconductor channel layer, and the second sidewall is in contact with the third semiconductor channel layer.

In some embodiments, the second semiconductor channel layer is wider than the third semiconductor channel layer along the second direction.

In some embodiments, the second semiconductor channel layer and the third semiconductor channel layer have substantially a same width along the second direction.

In some embodiments, in a top view, the first sidewall of the dielectric wall has a stepped profile, while the second sidewall of the dielectric wall has a linear sidewall profile.

In some embodiments, in a top view, the first and second sidewalls of the dielectric wall both have a stepped profile.

In some embodiments, a width between the first and second sidewalls under a gate structure of the pull-down transistor is less than a width between the first and second sidewalls under a gate structure of the pass-gate transistor.

In some embodiments, a width between the first and second sidewalls under a gate structure of the pull-down transistor is substantially equal to a width between the first and second sidewalls under a gate structure of the pass-gate transistor.

In some embodiments of the present disclosure, a method includes forming a first epitaxial stack and a second epitaxial stack over a substrate, wherein the first epitaxial stack comprising alternating first semiconductor layers and first sacrificial layers, and the second epitaxial stack comprising alternating second semiconductor layers and second sacrificial layers, wherein in a top view, each of the first semiconductor layers of the first epitaxial stack has a stepped sidewall; forming a dielectric wall between the first and second epitaxial stacks, wherein the dielectric wall is in contact with the stepped sidewall of each of the first semiconductor layers of the first epitaxial stack; removing the first and second sacrificial layers, leaving the first semiconductor layers and the second semiconductor layers remaining on opposite sides of the dielectric wall; and forming first and second gate structures over the first semiconductor layers and the second semiconductor layers.

In some embodiments, in the top view, each of the second semiconductor layers has a stepped sidewall, and wherein the dielectric wall interfaces with the stepped sidewall of each of the second semiconductor layers.

In some embodiments, in the top view, each of the second semiconductor channel layers has a linear sidewall, and wherein the dielectric wall interfaces with the linear sidewall of the each of the second semiconductor layers.

In some embodiments, each of the first semiconductor layers has a first portion under the first gate structure and a second portion under the second gate structure, wherein in the top view the first portion is wider than the second portion along a direction parallel to a lengthwise direction of the first gate structure.

In some embodiments, each of the second semiconductor layers is narrower than the second portion of each of the first semiconductor layers along the direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first transistor, comprising:
a plurality of first semiconductor channel layers;
a first gate structure over the plurality of first semiconductor channel layers; and
first source/drain structures on opposite sides of the first gate structure;
a second transistor, comprising:
a plurality of second semiconductor channel layers;
a second gate structure over the plurality of second semiconductor channel layers; and
second source/drain structures on opposite sides of the second gate structure; and
a dielectric wall comprising a first sidewall abutting side surfaces of the plurality of first semiconductor channel layers in a first cross-sectional view taken along a longitudinal axis of the first gate structure, the first sidewall of the dielectric wall also abutting side surfaces of the plurality of second semiconductor channel layers in a second cross-sectional view taken along a longitudinal axis of the second gate structure, wherein in a top view, the first sidewall of the dielectric wall has a stepped profile.

2. The device of claim 1, wherein in the top view, a second sidewall of the dielectric wall has a linear sidewall profile, the second sidewall being opposite to the first sidewall.

3. The device of claim 1, wherein in the top view, a second sidewall of the dielectric wall has a stepped profile, the second sidewall being opposite to the first sidewall.

4. The device of claim 1, wherein the dielectric wall further comprises second sidewall opposite the first sidewall, wherein a width between the first and second sidewalls under the first gate structure is less than a width between the first and second sidewalls under the second gate structure.

5. The device of claim 1, wherein the dielectric wall further comprises second sidewall opposite the first sidewall, wherein a width between the first and second sidewalls under the first gate structure is substantially equal to a width between the first and second sidewalls under the second gate structure.

6. The device of claim 1, wherein the plurality of first semiconductor channel layers are wider than the plurality of second semiconductor channel layers along a direction parallel to the longitudinal axis of the first gate structure.

7. The device of claim 1, further comprising:
a third transistor, comprising:
a plurality of third semiconductor channel layers;
a third gate structure over the plurality of third semiconductor channel layers; and
third source/drain structures on opposite sides of the third gate structure, wherein in the first cross-sectional view, a second sidewall of the dielectric wall is in contact with the plurality of third semiconductor channel layers, the second sidewall being opposite to the first sidewall.

8. The device of claim 7, wherein the plurality of first semiconductor channel layers are wider than the plurality of second semiconductor channel layers along a direction parallel to the longitudinal axis of the first gate structure, and the plurality of second semiconductor channel layers are wider than the plurality of third semiconductor channel layers along the direction.

9. A memory device, comprising:
a pull-down transistor having a first semiconductor channel layer;
a pass-gate transistor having a second semiconductor channel layer;
a pull-up transistor having a third semiconductor channel layer, wherein the pull-down transistor and the pass-gate transistor are arrange along a first direction, and the pull-down transistor and the pull-up transistor are arrange along a second direction perpendicular to the first direction, and wherein the first semiconductor channel layer is wider than the second semiconductor channel layer along the second direction; and
a dielectric wall having a first sidewall and a second sidewall opposite to the first sidewall, wherein the first sidewall is in contact with the first semiconductor channel layer and the second semiconductor channel layer, and the second sidewall is in contact with the third semiconductor channel layer.

10. The memory device of claim 9, wherein the second semiconductor channel layer is wider than the third semiconductor channel layer along the second direction.

11. The memory device of claim 9, wherein the second semiconductor channel layer and the third semiconductor channel layer have substantially a same width along the second direction.

12. The memory device of claim 9, wherein in a top view, the first sidewall of the dielectric wall has a stepped profile, while the second sidewall of the dielectric wall has a linear sidewall profile.

13. The memory device of claim 9, wherein in a top view, the first and second sidewalls of the dielectric wall both have a stepped profile.

14. The memory device of claim 9, wherein a width between the first and second sidewalls under a gate structure of the pull-down transistor is less than a width between the first and second sidewalls under a gate structure of the pass-gate transistor.

15. The memory device of claim 9, wherein a width between the first and second sidewalls under a gate structure of the pull-down transistor is substantially equal to a width between the first and second sidewalls under a gate structure of the pass-gate transistor.

16. A method, comprising:
forming a first epitaxial stack and a second epitaxial stack over a substrate, wherein the first epitaxial stack comprising alternating first semiconductor layers and first sacrificial layers, and the second epitaxial stack comprising alternating second semiconductor layers and second sacrificial layers, wherein in a top view, each of the first semiconductor layers of the first epitaxial stack has a stepped sidewall;
forming a dielectric wall between the first and second epitaxial stacks, wherein the dielectric wall is in contact with the stepped sidewall of each of the first semiconductor layers of the first epitaxial stack;
removing the first and second sacrificial layers, leaving the first semiconductor layers and the second semiconductor layers remaining on opposite sides of the dielectric wall; and
forming first and second gate structures over the first semiconductor layers and the second semiconductor layers.

17. The method of claim 16, wherein in the top view, each of the second semiconductor layers has a stepped sidewall, and wherein the dielectric wall interfaces with the stepped sidewall of each of the second semiconductor layers.

18. The method of claim 16, wherein in the top view, each of the second semiconductor layers has a linear sidewall, and wherein the dielectric wall interfaces with the linear sidewall of the each of the second semiconductor layers.

19. The method of claim 16, wherein each of the first semiconductor layers has a first portion under the first gate structure and a second portion under the second gate structure, wherein in the top view the first portion is wider than the second portion along a direction parallel to a lengthwise direction of the first gate structure.

20. The method of claim 19, wherein each of the second semiconductor layers is narrower than the second portion of each of the first semiconductor layers along the direction.
